(19) United States
(12) Patent Application Publication
(10) Pub. No.: US 2025/0154648 A1
(43) Pub. Date: May 15, 2025

(54) PRECURSOR FOR FORMING METAL THIN FILM, MANUFACTURING METHOD USING THE SAME, AND METAL THIN FILM MANUFACTURED THEREBY

(71) Applicant: Samsung Electronics Co., Ltd., Suwon-si (KR)

(72) Inventors: Hyunwoo KIM, Suwon-si (KR); Daeun KIM, Suwon-si (KR); Akio SAITO, Suwon-si (KR); Tomoharu YOSHINO, Suwon-si (KR); Kazuki HARANO, Suwon-si (KR); Takashi HIGASHINO, Suwon-si (KR); Shotaro TAGUCHI, Suwon-si (KR); Yoshiki MANABE, Suwon-si (KR); Yu Jin PARK, Suwon-si (KR); Byung Seok LEE, Suwon-si (KR); Seung-min RYU, Suwon-si (KR); Gyu-Hee PARK, Suwon-si (KR); Younjoung CHO, Suwon-si (KR)

(73) Assignees: Samsung Electronics Co., Ltd., Suwon-si (KR); ADEKA CORPORATION, Tokyo (JP); ADEKA KOREA Corporation, Wanju_gun (KR)

(21) Appl. No.: 18/791,776

(22) Filed: Aug. 1, 2024

(30) Foreign Application Priority Data
Nov. 13, 2023 (KR) 10-2023-0156357

(51) Int. Cl. C23C 16/34; C07F 17/00; C23C 16/44; C23C 16/448; C23C 16/455

(52) U.S. Cl. CPC C23C 16/34; C07F 17/00; C23C 16/4408; C23C 16/4485; C23C 16/45536; C23C 16/45553

(57) ABSTRACT

Provided are a precursor for forming a metal thin film including a metal compound represented by Chemical Formula 1, a method for manufacturing a metal thin film using the same, and a metal thin film manufactured by the method.

### CROSS-REFERENCE TO RELATED APPLICATION

This application claims priority to and the benefit of Korean Patent Application No. 10-2023-0156357, filed in the Korean Intellectual Property Office on Nov. 13, 2023, the entire contents of which are incorporated herein by reference.

### BACKGROUND

### 1. Field

This disclosure relates to precursor for forming a metal thin film, a method for manufacturing a metal thin film using the same, and/or a metal thin film manufactured thereby.

### 2. Description of the Related Art

When manufacturing semiconductor devices, atomic layer deposition (ALD) or chemical vapor deposition (CVD) processes are applied to form capacitor dielectric films or gate insulating films of transistors, and various types of organometallic compounds have been developed as precursors for these processes.

As such an organometallic compound precursor, hafnium or zirconium oxide, which has excellent high-K electrical properties, can be used.

Hafnium oxide (HfO₂) has a high dielectric constant material and has excellent properties such as a wide band gap, high refractive index, ferroelectric properties, and good thermal stability. Therefore, HfO₂ is used to form capacitor inductors in dynamic random access memory (DRAM) devices, gate insulator layers in metal oxide semiconductor field effect transistors (MOSFETs), tunnel gate dielectrics in flash memory circuits, etc.

A method for producing a thin film of HfO₂ may include, for example, a sputtering method, an ion plating method, an MOD method such as a coating pyrolysis method or a sol-gel method, and a CVD method. Among these, the atomic layer deposition method (sometimes referred to as the ALD method) may have excellent composition controllability and step coverage. ALD may be suitable for mass production and may enable hybrid integration.

Several materials that can be used in vapor phase thin film formation methods, such as CVD and ALD, have been reported. However, the raw material for thin film formation applicable to the ALD method needs to have a temperature range called the ALD window, and this temperature range needs to be sufficiently wide. Therefore, it is common knowledge in the technical field that even if the raw materials for thin film formation can be used in the CVD method, there are many cases in which they are not suitable for the ALD method.

There is a need to develop a metal precursor with a high dielectric constant that can produce thin films of high purity with excellent vapor pressure and thermal stability.

### SUMMARY

One aspect of the present disclosure is to provide a precursor for forming a metal thin film with excellent thermal stability.

Another aspect of the present disclosure is to provide a method for manufacturing a metal thin film using the precursor for forming the metal thin film.

Another aspect of the present disclosure is to provide a metal thin film manufactured according to the method for manufacturing the metal thin film.

According to an embodiment, a precursor for forming a metal thin film may include a metal compound represented by Chemical Formula 1.

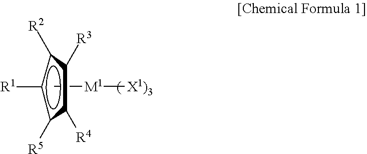

In Chemical Formula 1,
M¹ may be a Group 4 metal,
X¹ may be a halogen atom, and
R¹, R², R³, R⁴, and R⁵ each independently may be a hydrogen atom, a substituted or unsubstituted C1 to C5 alkyl group, or a ligand described as (L-1), or a combination of the ligand represented by (L-1) and a substituted or unsubstituted C1 to C5 alkyl group, provided that at least one of R¹, R², R³, R⁴, and R⁵ includes a substituted or unsubstituted C1 to C5 alkyl group or the ligand represented by (L-1),

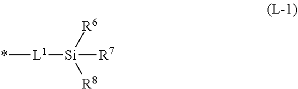

wherein, in (L-1), R⁶, R⁷, and R⁸ each independently may be a substituted or unsubstituted C1 to C5 alkyl group,
L¹ may be a single bond or a substituted or unsubstituted C1 to C5 alkylene group, and
* may be a linking point.

According to an embodiment, a method for manufacturing a metal thin film may include supplying a raw material gas obtained by vaporizing raw materials including the precursor into a deposition chamber; and forming a metal thin film including a Group 4 metal material on a surface of a substrate by heating or plasma treating the raw material gas while the raw material gas may be in the deposition chamber and a substrate may be in the deposition chamber.

According to another aspect, a metal thin film manufactured by the aforementioned method may be provided.

The precursor for forming a metal thin film according to one aspect has high thermal stability, so that a high-purity metal thin film can be stably manufactured, and in particular, it can provide raw materials optimized for chemical vapor growth.

A precursor for forming a metal thin film capable of producing a high-quality zirconium-containing thin film or hafnium-containing thin film with low residual carbon or residual chlorine and a method for manufacturing a thin film using the same may be provided.

### BRIEF DESCRIPTION OF THE DRAWINGS

FIG. 1 is a schematic view showing an example of an ALD device used in a method for manufacturing a thin film according to an example embodiment.

FIG. 2 is a schematic view showing another example of an ALD device used in a method for manufacturing a thin film according to an example embodiment.

FIG. 3 is a schematic view showing another example of an ALD device used in a method for manufacturing a thin film according to an example embodiment.

FIG. 4 is a schematic view showing another example of an ALD device used in a method for manufacturing a thin film according to an example embodiment.

FIG. 5 shows differential scanning calorimetry (DSC) results. In FIG. 5, “DSC mW/mg” on the vertical axis represents a change in heat quantity, and “Temp ° C.” on the horizontal axis represents a change in temperature.

FIG. 6 is a graph showing the growth rate of the deposition film according to the raw material input time.

FIG. 7 is a graph showing the results of thermal decomposition according to temperature change.

### DETAILED DESCRIPTION

The present disclosure will be described more fully hereinafter with reference to the accompanying drawings, in which example embodiments of inventive concepts are shown. Embodiments of inventive concepts may be implemented in many different forms and are not limited to the embodiments described herein.

In order to clearly describe the present disclosure, parts which are not related to the description are omitted, and the same reference numeral refers to the same or like components, throughout the specification.

As used herein, the term “and/or” includes any and all combinations of one or more of the associated listed items. Expressions such as “at least one of,” if preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

The size and thickness of each constituent element as shown in the drawings are randomly indicated for better understanding and ease of description, and this disclosure is not necessarily limited to as shown. In the drawings, the thickness of layers, films, panels, regions, etc., are exaggerated for clarity. In the drawings, the thickness of a portion of layers or regions, etc., may be exaggerated for clarity.

In addition, it will be understood that when an element such as a layer, film, region, or substrate is referred to as being “on” another element, it can be directly on the other element or intervening elements may also be present. In contrast, when an element is referred to as being “directly on” another element, there are no intervening elements present. Also, to be disposed “on” the reference portion is to be disposed above or below the reference portion and does not necessarily mean “above” toward an opposite direction of gravity.

In addition, unless explicitly described to the contrary, the word “comprise,” and variations such as “comprises” or “comprising,” will be understood to imply the inclusion of stated elements but not the exclusion of any other elements.

As used herein, “substituted” refers to replacement of at least one hydrogen by a substituent selected from a halogen atom (F, Cl, Br, or I), a hydroxy group, a C1 to C20 alkoxy group, a nitro group, a cyano group, an amine group, an imino group, an azido group, an amidino group, a hydrazino group, a hydrazono group, a carbonyl group, a carbamyl group, a thiol group, an ester group, an ether group, a carboxyl group or a salt thereof, a sulfonic acid group or a salt thereof, a phosphoric acid group or a salt thereof, a C1 to C20 alkyl group, a C2 to C20 alkenyl group, a C2 to C20 alkynyl group, a C6 to C20 aryl group, a C3 to C20 cycloalkyl group, a C3 to C20 cycloalkenyl group, a C3 to C20 cycloalkynyl group, a C2 to C20 heterocycloalkyl group, a C2 to C20 heterocycloalkenyl group, a C2 to C20 heterocycloalkynyl group, a C3 to C20 heteroaryl group, or a combination thereof.

As used herein, “Me” refers to a substituted or unsubstituted methyl group.

As used herein, “Et” refers to a substituted or unsubstituted ethyl group.

As used herein, “Pr” refers to a substituted or unsubstituted propyl group.

As used herein, “Bu” refers to a substituted or unsubstituted butyl group.

As used herein, “TMS” refers to a trimethylsilyl group.

As used herein, “Cp” refers to a substituted or unsubstituted C5 to C8 cycloalkenyl group.

### Precursor for Forming Metal Thin Film

An embodiment provides a precursor for forming a metal thin film including a metal compound represented by Chemical Formula 1.

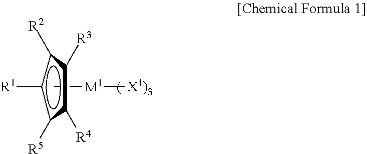

In Chemical Formula 1,
M¹ may be a Group 4 metal,
X¹ may be a halogen atom, and
R¹, R², R³, R⁴, and R⁵ each independently may be a hydrogen atom, a substituted or unsubstituted C1 to C5 alkyl group, or a ligand described as (L-1), or a combination of the ligand represented by (L-1) and a substituted or unsubstituted C1 to C5 alkyl group, provided that at least one of R¹, R², R³, R⁴, and R⁵ includes a substituted or unsubstituted C1 to C5 alkyl group or the ligand represented by (L-1),

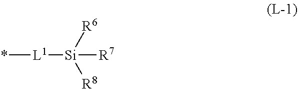

wherein, in (L-1), R⁶, R⁷, and R⁸ each independently may be a substituted or unsubstituted C1 to C5 alkyl group,
L¹ may be a single bond or a substituted or unsubstituted C1 to C5 alkylene group, and
is a linking point.

At least one of R¹, R², R³, R⁴, and R⁵ may be a substituted or unsubstituted C1 to C5 alkyl group or the ligand described in (L-1).

Many precursors for forming metal thin films have been reported. For example, Patent Document 1 describes tetrakis(dialkylamide)zirconium, and Patent Document 2 describes tetrakis(dialkylamide)hafnium. Additionally, Patent Document 3 describes a Group 4 element-containing compound including a cyclopetadienyl structure and an amine.
Patent Document 1: publication JP 2002-93803
Patent Document 2: publication JP 2002-93804
Patent Document 3: publication JP 2014-510733

However, when thin films are manufactured using the compounds described in Patent Documents 1 to 3, there have been a problem in that it is difficult to obtain thin films containing high-quality zirconium atoms or hafnium atoms with little residual carbon or residual chlorine.

In addition, conventional precursors for forming a metal thin film, for example precursors for forming hafnium-containing films, have low thermal stability with a thermal decomposition start temperature of less than about 350° C. during DSC analysis, making it difficult to form thin films through ALD at high temperatures above about 400° C.

In addition, conventional precursors for forming hafnium-containing films, such as HfCl₄, have high thermal stability, but are solid at room temperature and have a high melting point, making supply difficult when manufacturing metal thin films. There is also a problem with unused remaining volume, which led to low mass production and difficulty in securing process stability.

Therefore, embodiments of inventive concepts provide a precursor for forming a metal thin film type that can produce a thin film containing high-quality zirconium atoms or hafnium atoms with little residual carbon or residual chlorine (hereinafter sometimes referred to as a “zirconium-containing thin film or hafnium-containing thin film”) and a method for manufacturing a thin film using the same.

The precursor for forming a metal thin film according to embodiments of inventive concepts has a high thermal stability with a thermal decomposition start temperature of 500° C. or higher, so the ALD window is sufficiently wide, and thus mass production can be secured even at high temperatures, thereby improving process stability.

Examples of the substituted or unsubstituted C1 to C5 alkyl groups described in R¹, R², R³, R⁴, R⁵, R⁶, R⁷, and R⁸ may include a substituted or unsubstituted methyl group, a substituted or unsubstituted ethyl group, a substituted or unsubstituted n-propyl group, a substituted or unsubstituted iso-propyl group, a substituted or unsubstituted n-butyl group, a substituted or unsubstituted iso-butyl group, a substituted or unsubstituted sec-butyl group, a substituted or unsubstituted tert-butyl group, a substituted or unsubstituted n-pentyl group, a substituted or unsubstituted iso-pentyl group, a substituted or unsubstituted neo-pentyl group, and the like.

Examples of the substituted or unsubstituted C1 to C5 alkylene group described in L¹ may include a single bond, methylene, ethylene, propane-1,3-diyl, propane-1,2-diyl, butane-1,4-diyl, butane-1,3-diyl, butane-2,3-diyl, butane-1,2-diyl, pentane-1,1-diyl, pentane-1,2-diyl, pentane-1,3-diyl, pentane-1,4-diyl, pentane-1,5-diyl, and the like.

As an example, one or at least two of R¹, R², R³, R⁴, and R⁵ may be a substituted or unsubstituted C1 to C5 alkyl group or the ligand described as (L-1).

When the number of substituted or unsubstituted C1 to C5 alkyl groups among R¹, R², R³, R⁴, and R⁵ or the ligand described as (L-1) above, the melting point (M.P.) of the compound is low, thermal stability is high, and high-quality zirconium-containing thin films or hafnium-containing thin films with low residual carbon or residual chlorine can be easily manufactured with high productivity.

For example, one, two or five of R¹, R², R³, R⁴, and R⁵ may be substituted or unsubstituted C1 to C5 alkyl groups or the ligand described as (L-1).

As a specific example, one of R¹, R², R³, R⁴, and R⁵ may be a substituted or unsubstituted C1 to C5 alkyl group or the ligand described as (L-1). In this case, as a more specific example, one of R¹, R², R³, R⁴, and R⁵ may be a substituted or unsubstituted C3 to C5 branched alkyl group or a ligand described as (L-1), and for example, one of R¹, R², R³, R⁴, and R⁵ may be a substituted or unsubstituted iso-propyl group, a substituted or unsubstituted iso-butyl group, a substituted or unsubstituted sec-butyl group, a substituted or unsubstituted tert-butyl group, a substituted or unsubstituted iso-pentyl group, a substituted or unsubstituted neo-pentyl group, or a trimethylsilyl group as the ligand described in (L-1). As the most specific example, one of R¹, R², R³, R⁴, and R⁵ may be a substituted or unsubstituted sec-butyl group or a trimethylsilyl group as the ligand described as (L-1).

For example, at least two of R¹, R², R³, R⁴, and R⁵ may be substituted or unsubstituted C1 to C5 alkyl groups or the ligand described as (L-1).

As a specific example, two of R¹, R², R³, R⁴, and R⁵ may be a substituted or unsubstituted C1 to C5 alkyl group or the ligand described as (L-1).

In this case, as a more specific example, two of R¹, R², R³, R⁴, and R⁵ may be a combination of a substituted or unsubstituted C2 to C5 alkyl group and the ligand described as (L-1), or
two of R¹, R², R³, R⁴, and R⁵ may be a combination of a substituted or unsubstituted C1 to C5 alkyl group and a substituted or unsubstituted C1 to C5 alkyl group, specifically two of R¹, R², R³, R⁴, and R⁵ may be a combination of a substituted or unsubstituted C2 to C5 alkyl group and a substituted or unsubstituted C1 to C5 alkyl group, and more specifically, a combination of a substituted or unsubstituted C3 to C5 alkyl group and a substituted or unsubstituted C1 to C4 alkyl group.

In an embodiment, the combination of the substituted or unsubstituted C1 to C5 alkyl group and the ligand described as (L-1) may be a combination of one selected from a substituted or unsubstituted ethyl group, a substituted or unsubstituted n-propyl group, a substituted or unsubstituted iso-propyl group, a substituted or unsubstituted n-butyl group, a substituted or unsubstituted iso-butyl group, a substituted or unsubstituted sec-butyl group, a substituted or unsubstituted tert-butyl group, a substituted or unsubstituted n-pentyl group, a substituted or unsubstituted iso-pentyl group, and a substituted or unsubstituted neo-pentyl group, and a trimethylsilyl group as the ligand described in (L-1); or
in a specific embodiment, the combination of the substituted or unsubstituted C1 to C5 alkyl group and the ligand described as (L-1) may be a combination of one selected from a substituted or unsubstituted ethyl group, a substituted or unsubstituted iso-propyl group, a substituted or unsubstituted iso-butyl group, a substituted or unsubstituted sec-butyl group, and a substituted or unsubstituted tert-butyl group, and a trimethylsilyl group as the ligand described in (L-1); or
in a more specific embodiment, the combination of the substituted or unsubstituted C1 to C5 alkyl group and the ligand described as (L-1) may be a combination of a substituted or unsubstituted ethyl group or a substituted or unsubstituted sec-butyl group and a trimethylsilyl group as the ligand described in (L-1); or
in the most specific embodiment, the combination of the substituted or unsubstituted C1 to C5 alkyl group and the ligand described in (L-1) may be a combination of a substituted or unsubstituted ethyl group and a trimethylsilyl group as the ligand described in (L-1).

In an embodiment, the combination of the substituted or unsubstituted C2 to C5 alkyl group and the substituted or unsubstituted C1 to C5 alkyl group may be a combination of one selected from a substituted or unsubstituted ethyl group, a substituted or unsubstituted n-propyl group, a substituted or unsubstituted iso-propyl group, a substituted or unsubstituted n-butyl group, a substituted or unsubstituted iso-butyl group, a substituted or unsubstituted sec-butyl group, a substituted or unsubstituted tert-butyl group, a substituted or unsubstituted n-pentyl group, a substituted or unsubstituted iso-pentyl group, and a substituted or unsubstituted neo-pentyl group, and one selected from a substituted or unsubstituted methyl group, a substituted or unsubstituted iso-propyl group, a substituted or unsubstituted iso-butyl group, a substituted or unsubstituted sec-butyl group, a substituted or unsubstituted tert-butyl group, a substituted or unsubstituted iso-pentyl group, and a substituted or unsubstituted neo-pentyl group; or
in a specific embodiment, the combination of the substituted or unsubstituted C2 to C5 alkyl group and the substituted or unsubstituted C1 to C5 alkyl group may be a combination of one selected from a substituted or unsubstituted n-propyl group, a substituted or unsubstituted iso-propyl group, a substituted or unsubstituted n-butyl group, a substituted or unsubstituted iso-butyl group, a substituted or unsubstituted sec-butyl group, a substituted or unsubstituted tert-butyl group, a substituted or unsubstituted n-pentyl group, a substituted or unsubstituted iso-pentyl group, and a substituted or unsubstituted neo-pentyl group, and a substituted or unsubstituted methyl group; or
in a more specific embodiment, the combination of the substituted or unsubstituted C2 to C5 alkyl group and the substituted or unsubstituted C1 to C5 alkyl group may be a combination of a substituted or unsubstituted sec-butyl group and a substituted or unsubstituted sec-butyl group.

As a specific example, R¹, R², R³, R⁴, and R⁵ may all be substituted or unsubstituted C1 to C5 alkyl groups or the ligand described as (L-1).

In this case, as a more specific example, one of R¹, R², R³, R⁴, and R⁵ may be a substituted or unsubstituted C1 to C5 alkyl group or a ligand described as (L-1), and the remaining four may be a substituted or unsubstituted C1 to C5 alkyl group.

In an embodiment, the combination in which one of R¹, R², R³, R⁴, and R⁵ is a substituted or unsubstituted C1 to C5 alkyl group or a ligand described as (L-1), and the remaining four are a substituted or unsubstituted C1 to C5 alkyl group may be that one of R¹, R², R³, R⁴, and R⁵ may be a substituted or unsubstituted C2 to C5 alkyl group or the ligand described in (L-1), and the remaining four are substituted or unsubstituted C1 to C3 alkyl group; or
in a specific embodiment, one of R¹, R², R³, R⁴, and R⁵ may be one selected from a substituted or unsubstituted ethyl group, a substituted or unsubstituted n-propyl group, a substituted or unsubstituted iso-propyl group, a substituted or unsubstituted n-butyl group, a substituted or unsubstituted iso-butyl group, a substituted or unsubstituted sec-butyl group, a substituted or unsubstituted tert-butyl group, a substituted or unsubstituted n-pentyl group, a substituted or unsubstituted iso-pentyl group, a substituted or unsubstituted neo-pentyl group and trimethylsilyl group and the remaining four may be one selected from a substituted or unsubstituted methyl group, a substituted or unsubstituted ethyl group, and substituted or a substituted or unsubstituted n-propyl group.

In a more specific embodiment, one of R¹, R², R³, R⁴, and R⁵ may be one selected from a substituted or unsubstituted ethyl group, a substituted or unsubstituted n-propyl group, a substituted or unsubstituted iso-propyl group, a substituted or unsubstituted n-butyl group, a substituted or unsubstituted iso-butyl group, a substituted or unsubstituted sec-butyl group, a substituted or unsubstituted tert-butyl group, and a trimethylsilyl group, and the remaining four may be a substituted or unsubstituted methyl group.

In the most specific example, one of R¹, R², R³, R⁴, and R⁵ may be a substituted or unsubstituted n-butyl group, or a trimethylsilyl group, and the remaining four may be a substituted or unsubstituted methyl group.

For example, the Group 4 metal may be zirconium or hafnium.

As an example, X¹ may be F, C1, or a combination thereof (e.g., some X¹ in Chemical Formula 1 may be F and some X¹ may be Cl).

As an example, the metal compound represented by Chemical Formula 1 may be in a liquid state at room temperature (25° C.) and normal pressure (760 Torr).

In particular, when the metal compound represented by Chemical Formula 1 is a liquid, the precursor material may be vaporized in a diluted state in a solvent and may be transported into the deposition chamber in a more uniform state, so that it can be evenly adsorbed on the substrate, and as a result, the uniformity and step coverage characteristics of the deposited thin film can be improved.

As an example, the metal compound represented by Chemical Formula 1 may be at least one selected from Hf(sec-Bu)Cp(F)₃, Hf(TMS)Cp(F)₃, Hf(TMSCH₂)Cp(F)₃, Hf(Me₂Cp)(F)₃, Hf(Et₂Cp)(F)₃, Hf(n-Pr)₂Cp(F)₃, Hf(iso-Pr)Cp(F)₃, Hf(n-Bu)₂Cp(F)₃, Hf(iso-Bu)₂Cp(F)₃, Hf(sec-Bu)₂Cp(F)₃, Hf(tert-Bu)₂Cp(F)₃, Hf(TMS)₂Cp(F)₃, Hf(Me)(Et)Cp(F)₃, Hf(n-Pr)(Me)Cp(F)₃, Hf(iso-Pr)(Me)Cp(F)₃, Hf(n-Bu)(Me)Cp(F)₃, Hf(iso-Bu)(Me)Cp(F)₃, Hf(sec-Bu)(Me)Cp(F)₃, Hf(tert-Bu)(Me)Cp(F)₃, Hf(n-Pr)(Et)Cp(F)₃, Hf(n-Bu)(Et)Cp(F)₃, Hf(sec-Bu)(Et)Cp(F)₃, Hf(n-Bu)(n-Pr)Cp(F)₃, Hf(sec-Bu)(n-Pr)Cp(F)₃, Hf(Me)(TMS)Cp(F)₃, Hf(Et)(TMS)Cp(F)₃, Hf(n-Pr)(TMS)Cp(F)₃, Hf(iso-Pr)(TMS)Cp(F)₃, Hf(n-Bu)(TMS)Cp(F)₃, Hf(iso-Bu)(TMS)Cp(F)₃, Hf(sec-Bu)(TMS)Cp(F)₃, Hf(tert-Bu)(TMS)Cp(F)₃, Hf(Me₅)Cp(F)₃, Hf(Me₄)(Et)Cp(F)₃, Hf(Me₄)(n-Pr)Cp(F)₃, Hf(Me₄)(n-Bu)Cp(F)₃;
Hf(sec-Bu)Cp(Cl)₃, Hf(TMS)Cp(Cl)₃, Hf(TMSCH₂)Cp(Cl)₃, Hf(Me₂Cp)(Cl)₃, Hf(Et₂Cp)(Cl)₃, Hf(n-Pr)₂Cp(Cl)₃, Hf(iso-Pr)Cp(Cl)₃, Hf(n-Bu)₂Cp(Cl)₃, Hf(iso-Bu)₂Cp(Cl)₃, Hf(sec-Bu)₂Cp(Cl)₃, Hf(tert-Bu)₂Cp(Cl)₃, Hf(TMS)₂Cp(Cl)₃, Hf(Me)(Et)Cp(Cl)₃, Hf(n-Pr)(Me)Cp(Cl)₃, Hf(iso-Pr)(Me)Cp(Cl)₃, Hf(n-Bu)(Me)Cp(Cl)₃, Hf(iso-Bu)(Me)Cp(Cl)₃, Hf(sec-Bu)(Me)Cp(Cl)₃, Hf(tert-Bu)(Me)Cp(Cl)₃, Hf(n-Pr)(Et)Cp(Cl)₃, Hf(n-Bu)(Et)Cp(Cl)₃, Hf(sec-Bu)(Et)Cp(Cl)₃, Hf(n-Bu)(n-Pr)Cp(Cl)₃, Hf(sec-Bu)(n-Pr)Cp(Cl)₃, Hf(Me)(TMS)Cp(Cl)₃, Hf(Et)(TMS)Cp(Cl)₃, Hf(n-Pr)(TMS)Cp(Cl)₃, Hf(iso-Pr)(TMS)Cp(Cl)₃, Hf(n-Bu)(TMS)Cp(Cl)₃, Hf(iso-Bu)(TMS)Cp(Cl)₃, Hf(sec-Bu)(TMS)Cp(Cl)₃, Hf(tert-Bu)(TMS)Cp(Cl)₃, Hf(Me₅)Cp(Cl)₃, Hf(Me₄)(Et)Cp(Cl)₃, Hf(Me₄)(n-Pr)Cp(Cl)₃, Hf(Me₄)(n-Bu)Cp(Cl)₃;
Zr(sec-Bu)Cp(F)₃, Zr(TMS)Cp(F)₃, Zr(TMSCH₂)Cp(F)₃, Zr(Me₂Cp)(F)₃, Zr(Et₂Cp)(F)₃, Zr(n-Pr)₂Cp(F)₃, Zr(iso-Pr)Cp(F)₃, Zr(n-Bu)₂Cp(F)₃, Zr(iso-Bu)₂Cp(F)₃, Zr(sec-Bu)₂Cp(F)₃, Zr(tert-Bu)₂Cp(F)₃, Zr(TMS)₂Cp(F)₃, Zr(Me)(Et)Cp(F)₃, Zr(n-Pr)(Me)Cp(F)₃, Zr(iso-Pr)(Me)Cp(F)₃, Zr(n-Bu)(Me)Cp(F)₃, Zr(iso-Bu)(Me)Cp(F)₃, Zr(sec-Bu)(Me)Cp(F)₃, Zr(tert-Bu)(Me)Cp(F)₃, Zr(n-Pr)(Et)Cp(F)₃, Zr(n-Bu)(Et)Cp(F)₃, Zr(sec-Bu)(Et)Cp(F)₃, Zr(n-Bu)(n-Pr)Cp(F)₃, Zr(sec-Bu)(n-Pr)Cp(F)₃, Zr(Me)(TMS)Cp(F)₃, Zr(Et)(TMS)Cp(F)₃, Zr(n-Pr)(TMS)Cp(F)₃, Zr(iso-Pr)(TMS)Cp(F)₃, Zr(n-Bu)(TMS)Cp(F)₃, Zr(iso-Bu)(TMS)Cp(F)₃, Zr(sec-Bu)(TMS)Cp(F)₃, Zr(tert-Bu)(TMS)Cp(F)₃, Zr(Me₅)Cp(F)₃, Zr(Me₄)(Et)Cp(F)₃, Zr(Me₄)(n-Pr)Cp(F)₃, Zr(Me₄)(n-Bu)Cp(F)₃; and
Zr(sec-Bu)Cp(Cl)₃, Zr(TMS)Cp(Cl)₃, Zr(TMSCH₂)Cp(Cl)₃, Zr(Me₂Cp)(Cl)₃, Zr(Et₂Cp)(Cl)₃, Zr(n-Pr)₂Cp(Cl)₃, Zr(iso-Pr)Cp(Cl)₃, Zr(n-Bu)₂Cp(Cl)₃, Zr(iso-Bu)₂Cp(Cl)₃, Zr(sec-Bu)₂Cp(Cl)₃, Zr(tert-Bu)₂Cp(Cl)₃, Zr(TMS)₂Cp(Cl)₃, Zr(Me)(Et)Cp(Cl)₃, Zr(n-Pr)(Me)Cp(Cl)₃, Zr(iso-Pr)(Me)Cp(Cl)₃, Zr(n-Bu)(Me)Cp(Cl)₃, Zr(iso-Bu)(Me)Cp(Cl)₃, Zr(sec-Bu)(Me)Cp(Cl)₃, Zr(tert-Bu)(Me)Cp(Cl)₃, Zr(n-Pr)(Et)Cp(Cl)₃, Zr(n-Bu)(Et)Cp(Cl)₃, Zr(sec-Bu)(Et)Cp(Cl)₃, Zr(n-Bu)(n-Pr)Cp(Cl)₃, Zr(sec-Bu)(n-Pr)Cp(Cl)₃, Zr(Me)(TMS)Cp(Cl)₃, Zr(Et)(TMS)Cp(Cl)₃, Zr(n-Pr)(TMS)Cp(Cl)₃, Zr(iso-Pr)(TMS)Cp(Cl)₃, Zr(n-Bu)(TMS)Cp(Cl)₃, Zr(iso-Bu)(TMS)Cp(Cl)₃, Zr(sec-Bu)(TMS)Cp(Cl)₃, Zr(tert-Bu)(TMS)Cp(Cl)₃, Zr(Me₅)Cp(Cl)₃, Zr(Me₄)(Et)Cp(Cl)₃, Zr(Me₄)(n-Pr)Cp(Cl)₃, Zr(Me₄)(n-Bu)Cp(Cl)₃.

For example, the metal compound represented by Chemical Formula 1 may be at least one selected from the compounds listed in Group 1.

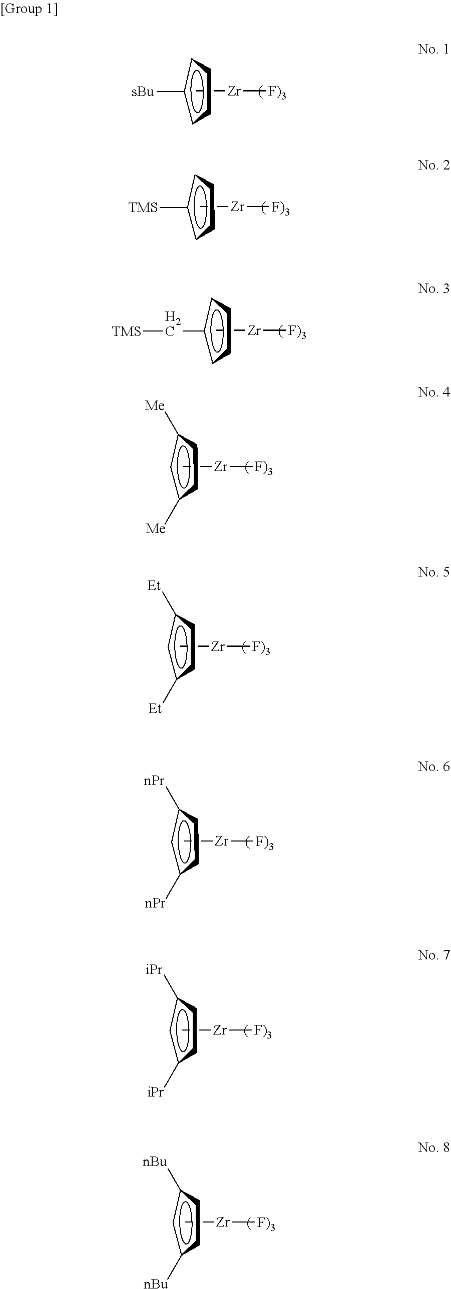

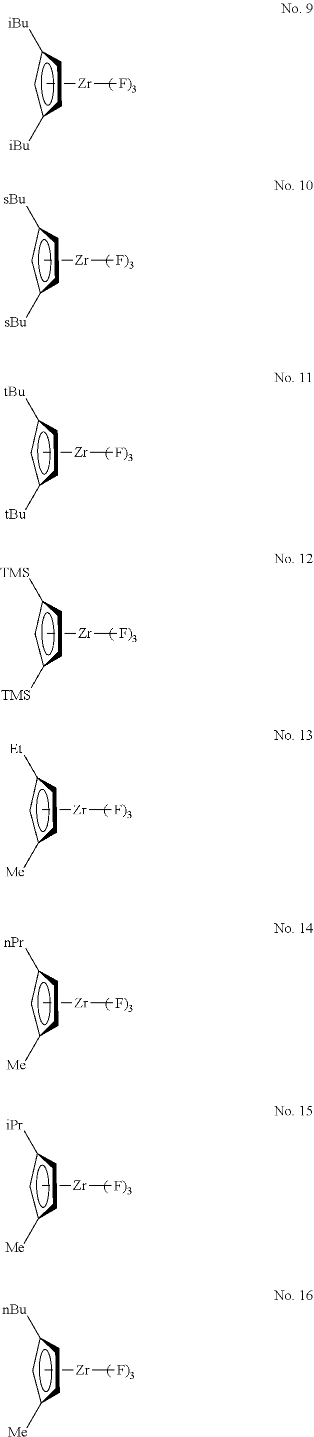

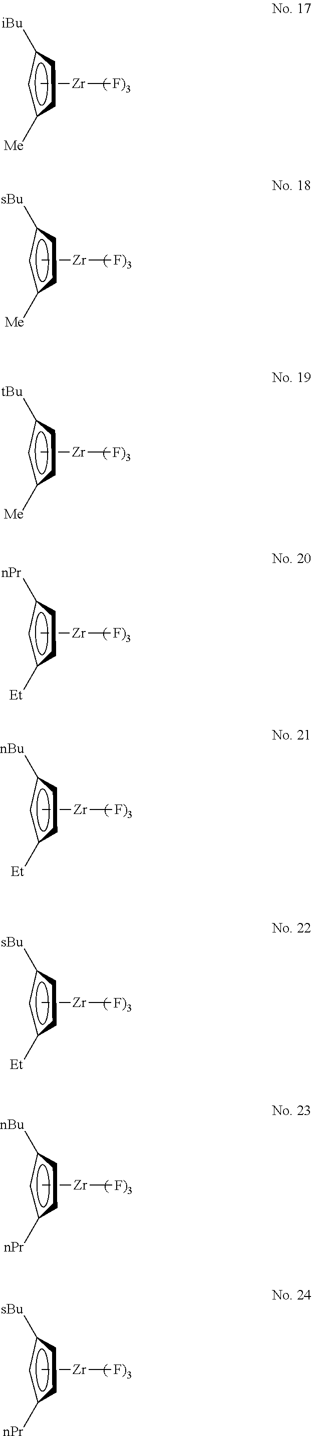

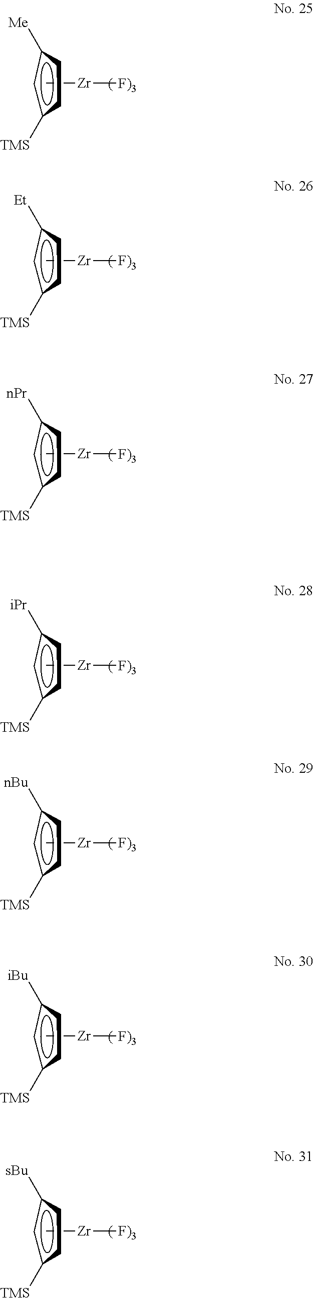

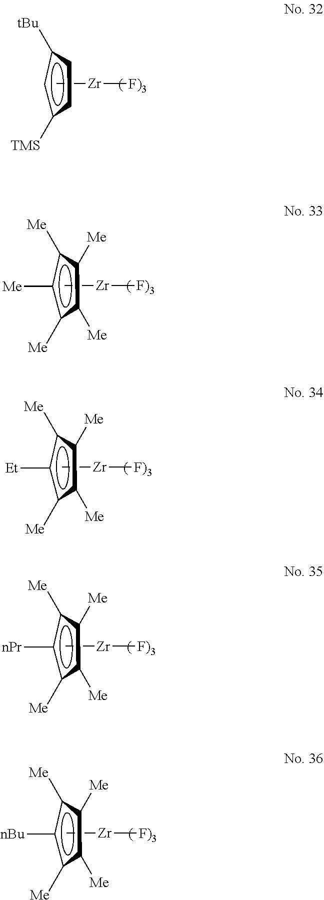

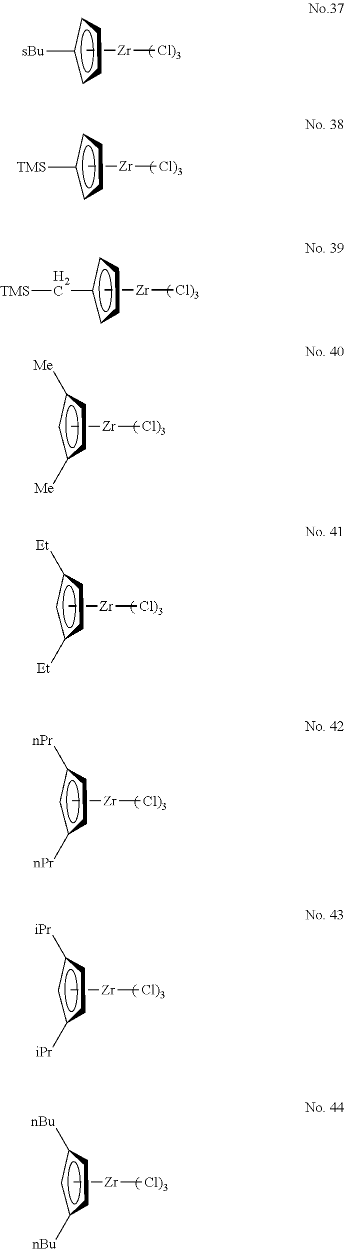

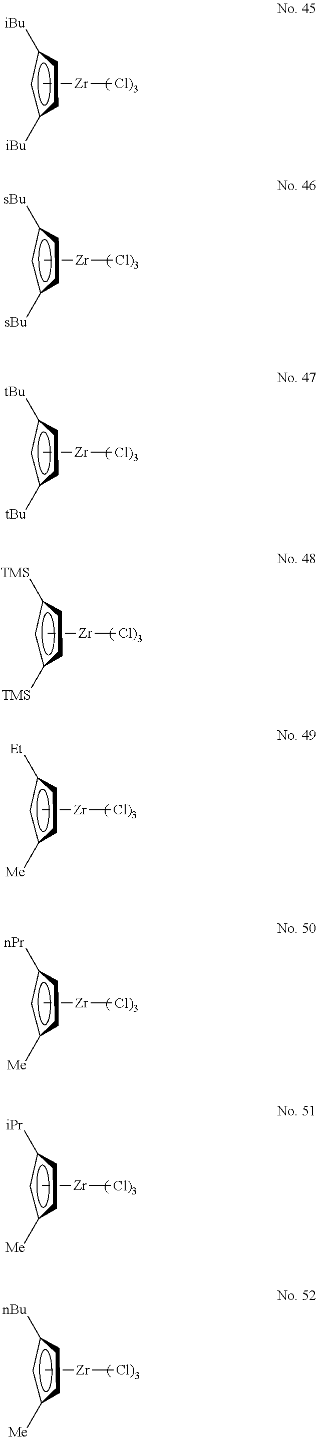

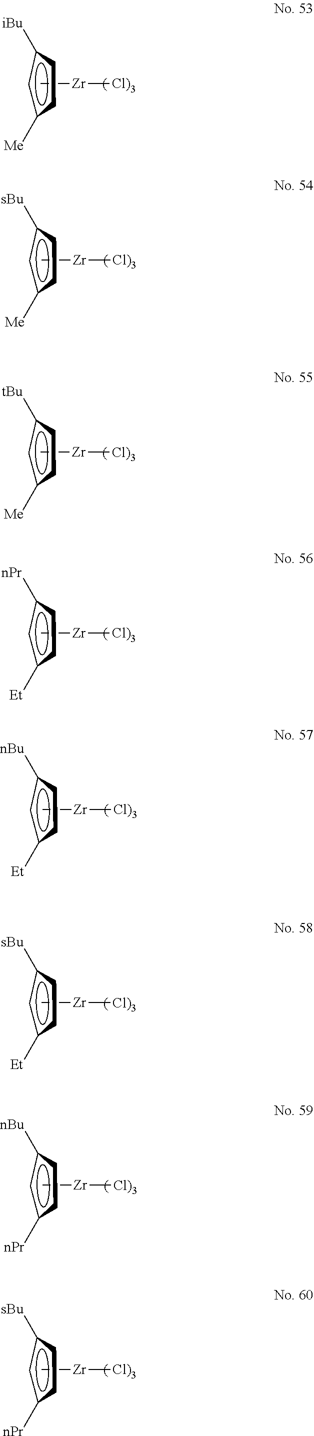

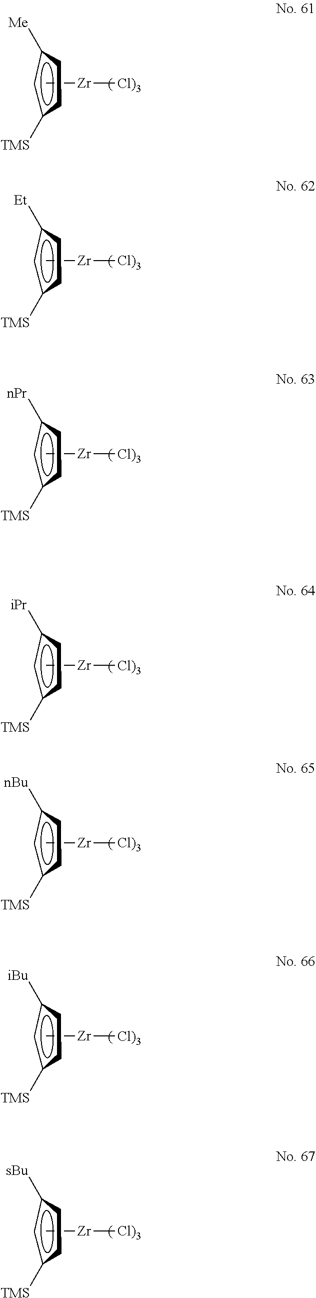

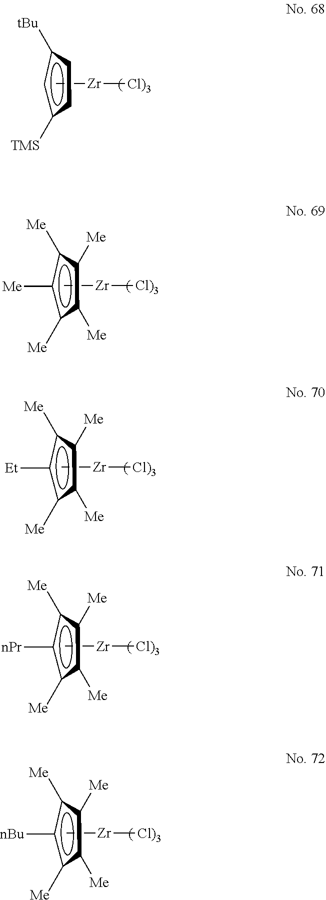

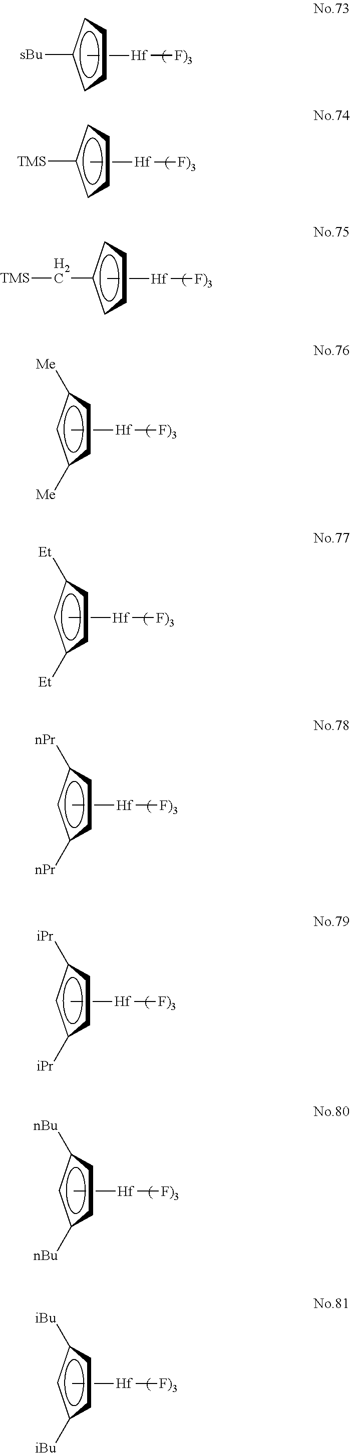

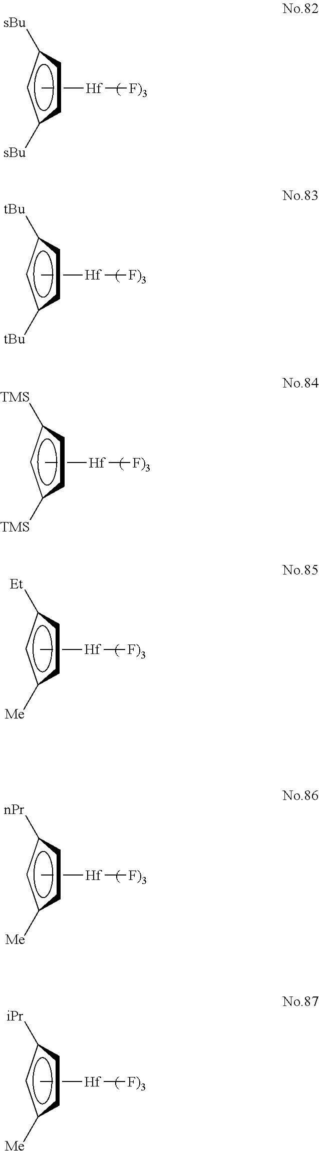

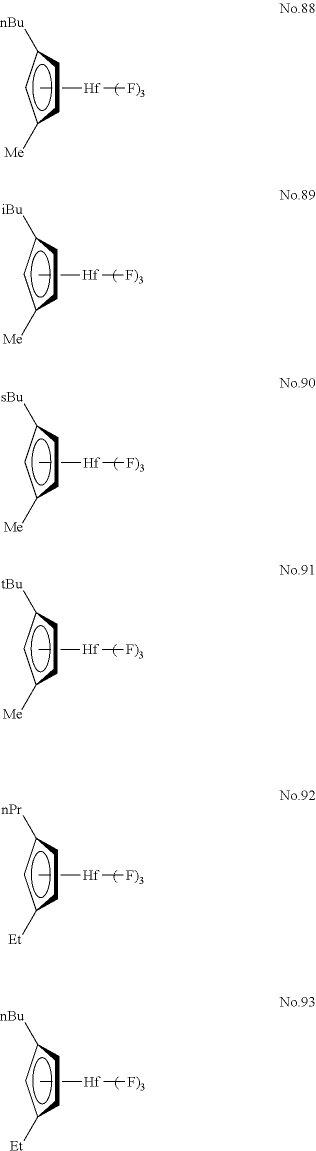

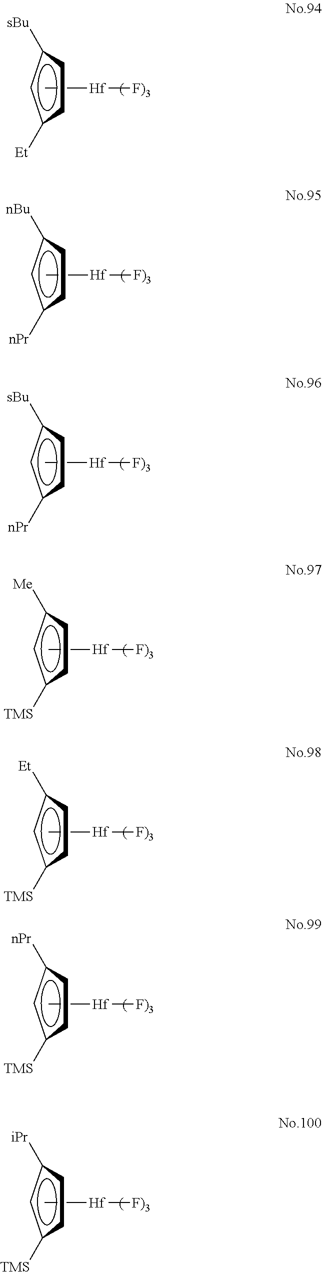

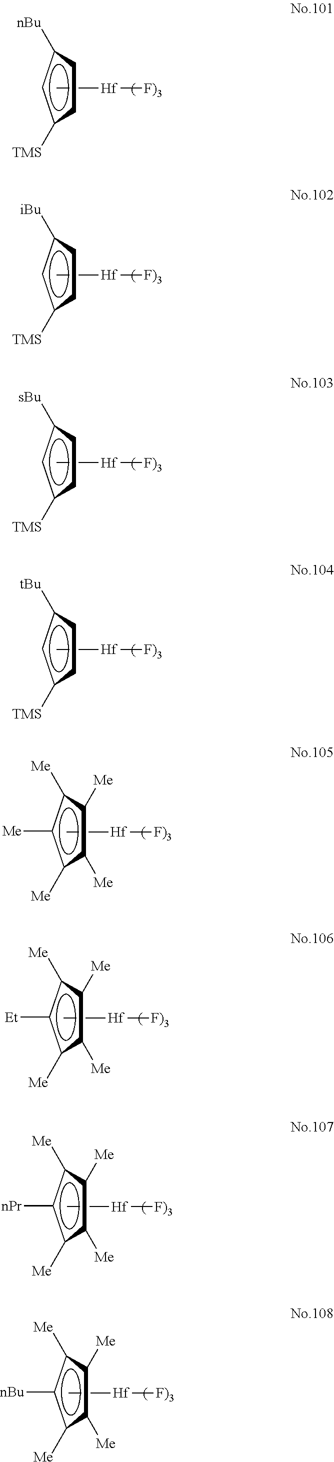

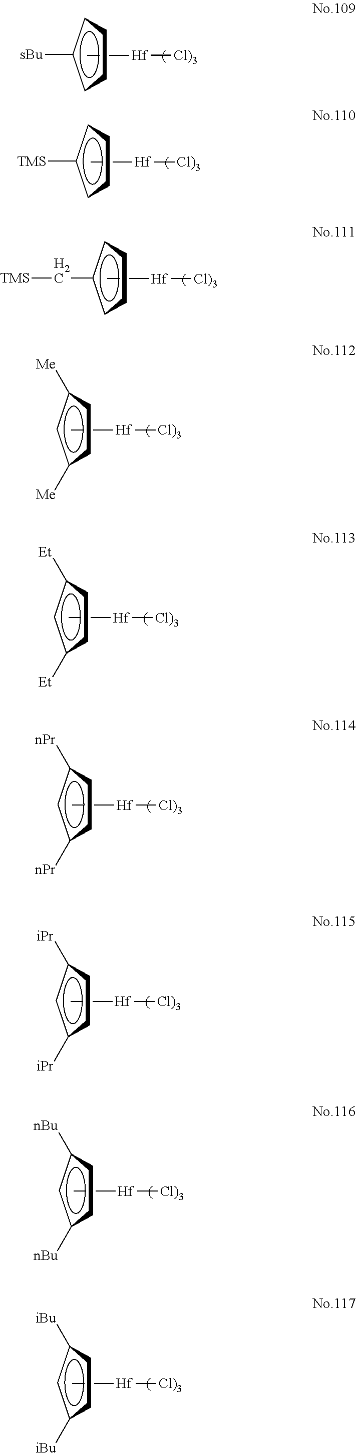

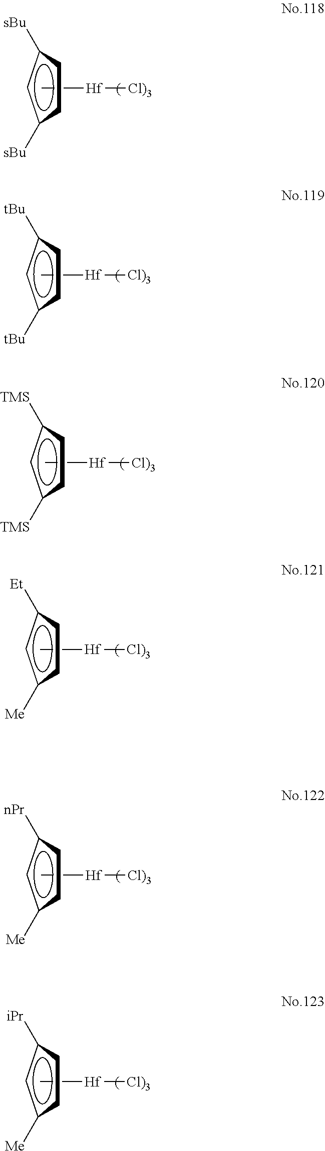

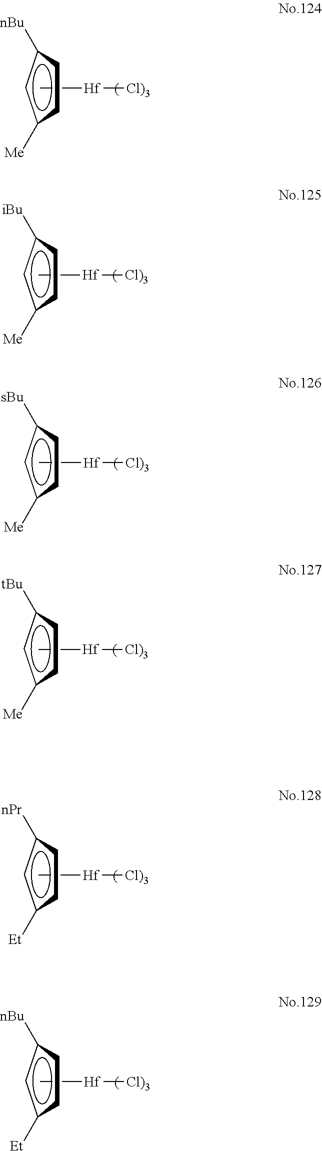

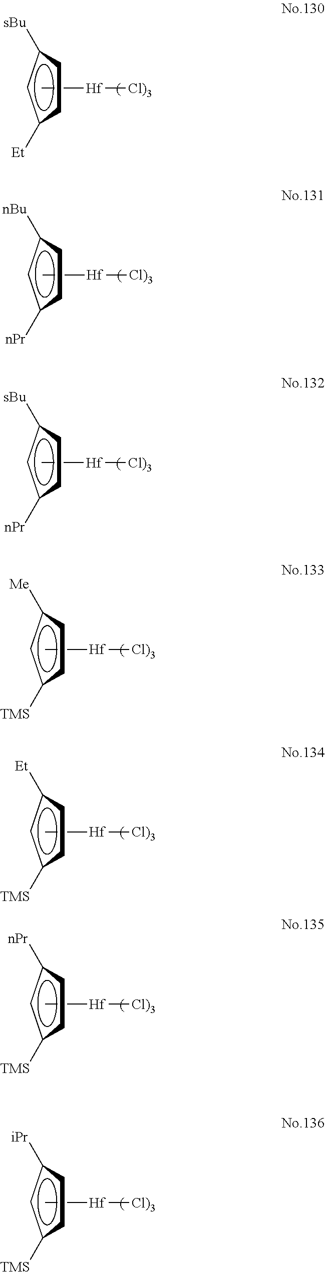

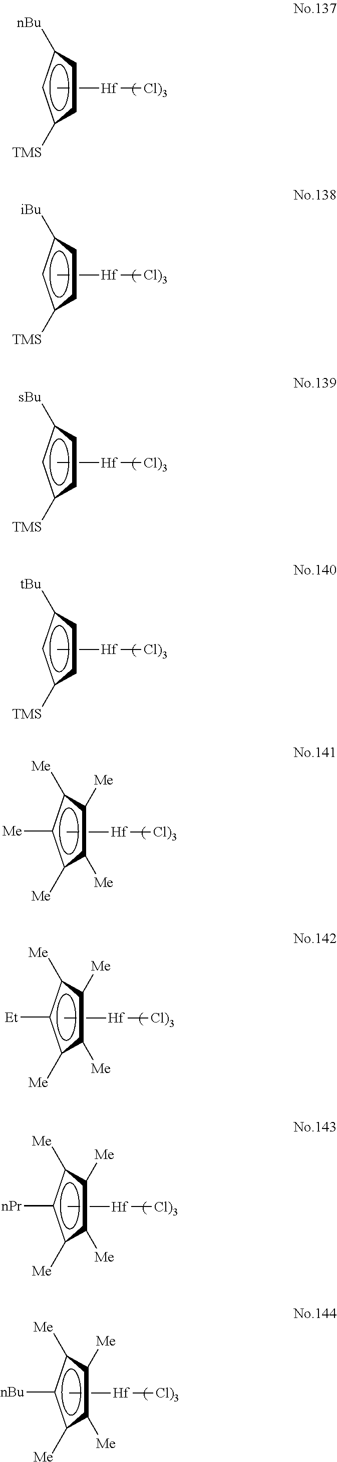

The compound described in Chemical Formula 1 used as a precursor for forming a metal thin film according to embodiments of inventive concepts is not subject to any particular restrictions on its manufacturing method and can be manufactured by applying a known synthesis method. For example, the compound shown in Chemical Formula 1 may be obtained by mixing and stirring zirconium tetrachloride or hafnium tetrachloride and a cyclopentadiene compound of the corresponding structure in the presence or absence of a solvent to react them, and then removing the solvent by distillation.

The compound shown in Chemical Formula 1 may be used as a precursor for forming a metal thin film according to embodiments of inventive concepts, and its composition may be vary depending on the type of thin film being targeted. For example, when manufacturing a thin film including only zirconium or hafnium atoms among metals, the precursor for forming the metal thin film does not include metal compounds or semimetal compounds other than zirconium or hafnium. On the other hand, when manufacturing a thin film including zirconium atoms or hafnium atoms and a metal or semimetal other than zirconium atoms or hafnium atoms, the precursor for forming a metal thin film may also include a compound including a desired metal or a compound including a semimetal (hereinafter sometimes referred to as “another precursor”), in addition to the compound described in Chemical Formula 1.

In the case of multi-component ALD using a plurality of precursors, there are no special restrictions as to other precursors that can be used together with the compound shown in Chemical Formula 1, and well-known general precursors used as precursors for forming metal thin films for ALD can be used.

The other precursors may include, for example, compounds including one or two or more types selected from compounds used as organic ligands such as alcohol compounds, glycol compounds, β-diketone compounds, cyclopentadiene compounds, and organic amine compounds, and Si and metals. Additionally, metal types of the precursor may include lithium, sodium, potassium, magnesium, calcium, strontium, barium, titanium, zirconium, hafnium, vanadium, niobium, tantalum, chromium, molybdenum, tungsten, manganese, iron, osmium, ruthenium, cobalt, rhodium, iridium, nickel, palladium, platinum, copper, silver, gold, zinc, aluminum, gallium, indium, germanium, lead, antimony, bismuth, radium, scandium, yttrium, lanthanum, cerium, praseodymium, neodymium, promethium, samarium, europium, gadolinium, terbium, dysprosium, holmium, erbium, thulium, ytterbium, or lutetium.

The alcohol compounds having organic ligands of the other precursors may include alkyl alcohols such as methanol, ethanol, propanol, isopropyl alcohol, butanol, secondary butyl alcohol, isobutyl alcohol, tertiary butyl alcohol, pentyl alcohol, isopentyl alcohol, and tertiary pentyl alcohol; ether alcohols such as 2-methoxyethanol, 2-ethoxyethanol, 2-butoxyethanol, 2-2-methoxyethoxy)ethanol, 2-methoxy-1-methylethanol, 2-methoxy-1,1-dimethylethanol, 2-ethoxy-1,1-dimethylethanol, 2-isopropoxy-1,1-dimethylethanol, 2-butoxy-1,1-dimethylethanol, 2-(2-methoxyethoxy)-1,1-dimethylethanol, 2-propoxy-1,1-di ethylethanol, 2-s-butoxy-1,1-diethylethanol, 3-methoxy-1,1-dimethylpropanol; dialkylaminoalcohols such as dimethylaminoethanol, ethylmethylaminoethanol, diethylaminoethanol, dimethylamino-2-pentanol, ethylmethylamino-2-pentanol, dimethylamino-2-methyl-2-pentanol, ethylmethylamino-2-methyl-2-pentanol, diethylamino-2-methyl-2-pentanol, and the like.

The glycol compounds that can be used as organic ligands for the other precursors may include 1,2-ethanediol, 1,2-propanediol, 1,3-propanediol, 2,4-hexanediol, 2,2-dimethyl-1,3-propanediol, 2,2-diethyl-1,3-propanediol, 1,3-butanediol, 2,4-butanediol, 2,2-diethyl-1,3-butanediol, 2-ethyl-2-butyl-1,3-propanediol, 2,4-pentanediol, 2-methyl-1,3-propanediol, 2-methyl-2,4-pentanediol, 2,4-hexanediol, 2,4-dimethyl-2,4-pentanediol, and the like.

The β-diketone compounds that can be used as organic ligands for the other precursors may include alkyl-substituted β-diketones such as acetylacetone, hexane-2,4-dione, 5-methylhexane-2,4-dione, heptane-2,4-dione, 2-methylheptane-3,5-dione, 5-methylheptane-2,4-dione, 6-methylheptane-2,4-dione, 2,2-dimethylheptane-3,5-dione, 2,6-dimethylheptane-3,5-dione, 2,2,6-trimethylheptane-3,5-dione, 2,2,6,6-tetramethylheptane-3,5-dione, octane-2,4-dione, 2,2,6-trimethyloctane-3,5-dione, 2,6-dimethyloctane-3,5-dione, 2,9-dimethylnonane-4,6-dione, 2-methyl-6-ethyldecane-3,5-dione, 2,2-dimethyl-6-ethyldecane-3,5-dione, and the like; fluorine-substituted alkyl β-diketones such as 1,1,1-trifluoropentane-2,4-dione, 1,1,1-trifluoro-5,5-dimethylhexane-2,4-dione, 1,1,1,5,5,5-hexafluoropentane-2,4-dione, 1,3-diperfluorohexylpropane-1,3-dione, and the like; ether-substituted β-diketones such as 1,1,5,5-tetramethyl-1-methoxyhexane-2,4-dione, 2,2,6,6-tetramethyl-1-methoxyheptane-3,5-dione, 2,2,6,6-tetramethyl-1-(2-methoxyethoxy)heptane-3,5-dione, and the like.

The cyclopentadione compounds that can be used as organic ligands for the other precursors may include cyclopentadione, methylcyclopentadione, ethylcyclopentadione, propylcyclopentadione, isopropylcyclopentadione, butylcyclopentadione, secondary butylcyclopentadione, isobutylcyclopentadione, tertiary butylcyclopentadione, dimethylcyclopentadione, tetramethylcyclopentadione, and the like.

The amine compounds among the organic ligands of the other precursors may include methylamine, ethylamine, propylamine, isopropylamine, butylamine, secondary butylamine, tertiary butylamine, isobutylamine, dimethylamine, diethylamine, dipropylamine, diisopropylamine, ethylmethylamine, propylmethylamine, isopropylmethylamine, and the like.

As an example of a manufacturing method, when using an alcohol compound as an organic ligand, the precursor may be manufactured by reacting the above-mentioned metal inorganic salt or its hydrate with an alkali metal alkoxide of the alcohol compound.

Herein, the metal inorganic salt or its hydrate may include a metal halide, acetic acid, and the like. The alkaline metal alkoxide may be sodium alkoxide, lithium alkoxide, potassium alkoxide, and the like.

As described above, in multi-component ALD, a method of independently vaporizing and supplying precursors for forming a metal thin film according to each component (hereinafter sometimes referred to as the “single source method”), and a method of vaporizing and supplying mixed raw materials in which multi-component raw materials are mixed in advance to a desired composition (hereinafter sometimes referred to as the “cocktail sauce method”). In the case of the single source method, as the other precursors, suitable are compounds whose thermal decomposition or oxidative decomposition behavior is similar to the compound shown in Chemical Formula 1. In the case of the cocktail sauce method, as the other precursors, suitable are compounds that have similar thermal or oxidative decomposition behavior to the compounds shown in Chemical Formula 1 and do not deteriorate due to chemical reactions or the like when mixed.

In the case of the cocktail sauce method in multi-component ALD, a mixture of the compound shown in Chemical Formula 1 and other precursors, or a mixture of the mixture dissolved in an organic solvent, may be used as a precursor for forming a metal thin film.

The above organic solvent is not particularly limited, and general organic solvents may be used. Examples of the organic solvent may include, for example, acetate esters such as ethyl acetate, butyl acetate, methoxyethyl acetate, and the like; ethers such as tetrahydrofuran, tetrahydropyran, ethylene glycoldimethylether, diethylene glycoldimethylether triethylene glycoldimethylether, dibutylether, dioxane, and the like; ketones such as methyl butyl ketone, methyl isobutyl ketone, ethylbutylketone, dipropylketone, diisobutylketone, methylamylketone, cyclohexanone, methylcyclohexanone, and the like; hydrocarbons such as hexane, cyclohexane, methylcyclohexane, dimethylcyclohexane, ethylcyclohexane, heptane, octane, toluene, xylene, and the like; hydrocarbons with a cyano group such as 1-cyanopropane, 1-cyanobutane, 1-cyanohexane, cyanocyclohexane, cyanobenzene, 1,3-dicyanopropane, 1,4-dicyanobutane, 1,6-dicyanohexane, 1,4-dicyanocyclohexane, 1,4dicyanobenzene, and the like; pyridine, lutidine, and the like. These organic solvents may be used alone, or two or more types may be used in combination, depending on the solubility of the solute, the relationship between use temperature, boiling point, and flash point.

When the precursor for forming a metal thin film according to embodiments of inventive concepts is a mixed solution containing the above organic solvent, from the viewpoint of making it easy to form a high-quality zirconium-containing thin film or hafnium-containing thin film with low residual carbon or residual chlorine, it is appropriate to adjust a total amount of precursors included in the raw materials for forming a metal thin film to about 0.01 mol/L to about 2.0 mol/L, and more desirably to adjust it to about 0.05 mol/L to about 1.0 mol/L.

Herein, the total amount of the precursors refers to an amount of the compound shown in Chemical Formula 1 when the precursor for forming a metal thin film does not include precursors other than the compound shown in Chemical Formula 1.

When the raw material for forming a metal thin film includes other precursors in addition to the compound shown in Chemical Formula 1, it represents a sum of the compound shown in Chemical Formula 1 and the other precursors.

The precursor for forming a metal thin film according to embodiments of inventive concepts may, if necessary, include a nucleophilic reagent in order to improve the stability of the compound shown in Chemical Formula 1 and other precursors. Examples of the nucleophilic reagents may include ethylene glycol ethers such as glyme, diglyme, triglyme, tetraglyme, and the like, crown ethers such as 18-crown-6, dicyclohexyl-18-crown-6, 24-crown-8, dicyclohexyl-24-crown-8, dibenzo-24-crown-8, and the like; polyamine such as ethylenediamine, N,N′-tetramethylethylenediamine, diethylenetriamine, triethylenetetraamine, tetraethylenepentaamine, pentaethylenehexaamine, 1,1,4,7,7-pentamethyldiethylenetriamine, 1,1,4,7,10,10-hexamethyltriethylenetetraamine, triethoxytriethyleneamine, and the like; cyclic polyamines such as cyclam, cyclan, and the like; heterocyclic compounds such as pyridine, pyrrolidine, piperidine, morpholine, N-methylpyrrolidine, N-methylpiperidine, N-methylmorpholine, tetrahydrofuran, tetrahydropyran, 1,4-dioxane, oxazole, thiazole, oxathiophene, and the like; β-ketoesters such as methyl acetoacetate, ethyl acetoacetate, 2-methoxyethyl acetoacetate, and the like; β-diketones such as acetylacetone, 2,4-2,4-hexanedione, 2,4-heptanedione, 3,5-heptanedione, dipyvaroylmethane, and the like. From the viewpoint of easy adjustment of stability, an amount of this nucleophilic reagent used may be in the range of about 0.1 moles to about 10 moles, and more desirably in the range of about 1 mole to about 4 moles, per 1 mole of the total precursors.

The precursor for forming a metal thin film according to embodiments of inventive concepts may be desirably free from metal element impurities, halogen impurities such as chlorine impurities, and organic impurities other than those constituting the precursor. For metallic element impurities, about 100 ppb or less may be appropriate for each element, more desirably about 10 ppb or less, and the total amount may be desirably about 1 ppm or less, and more desirably about 100 ppb or less. In particular, when used as an LSI gate insulating film, gate film, barrier layer, or wiring layer, it is necessary to reduce a content of alkali metal elements and alkaline earth metal elements that affect the electrical characteristics of the obtained thin film. The halogen impurity component may be desirably about 100 ppm or less, more desirably about 10 ppm or less, and even more desirably about 1 ppm or less. The total amount of organic impurities may be desirably about 500 ppm or less, more desirably about 50 ppm or less, and even more desirably about 10 ppm or less. In addition, since moisture causes particle generation in the raw materials for thin film formation or particle generation during thin film formation, in order to reduce moisture in the precursor, organic solvent, and nucleophilic reagent, it is better to remove as much moisture as possible before use. An amount of moisture in each of the precursor, organic solvent, and nucleophilic reagent may be desirably about 10 ppm or less, and more desirably about 1 ppm or less. The precursor for forming a metal thin film according to embodiments of inventive concepts facilitates the production of high-quality zirconium-containing thin films or hafnium-containing thin films with low residual carbon or residual chlorine by controlling the metal element impurities, halogen impurity components, organic impurity components, and moisture below the above values.

In order to reduce or prevent particle contamination of the formed thin film, the precursor for forming a metal thin film according to embodiments of inventive concepts may be formed to contain as few particles as possible. Specifically, from the viewpoint of ease of obtaining a uniform zirconium-containing thin film or hafnium-containing thin film, it is suitable if the number of particles larger than about 0.3 μm may be about 100 or less per 1 mL of raw material for forming a metal thin film in particle measurement using a light scattering liquid particle detector in the liquid phase and it is suitable if the number of particles larger than about 0.2 μm may be about 100 or less per 1 mL of raw material for forming a metal thin film.

A thermal decomposition temperature of the metal compound represented by Chemical Formula 1 may be about 500° C. or higher.

### Manufacturing Method of Metal Thin Film

Hereinafter, an example of a method for manufacturing a metal thin film using the aforementioned precursor for forming a metal thin film will be described.

Another embodiment provides a method for manufacturing a metal thin film which includes a supply step of supplying raw material gas obtained by vaporizing raw materials including the aforementioned precursor for forming a metal thin film into a deposition chamber where a substrate is placed; and a thin film forming step of forming a thin film including a Group 4 metal material on the surface of a substrate by heating or plasma treating the aforementioned metal compound represented by Chemical Formula 1.

In particular, since it is easy to obtain a high-quality zirconium-containing thin film or hafnium-containing thin film with low residual carbon, the method may further include a precursor thin film forming step of forming a precursor thin film on the surface of the substrate using a precursor for forming a metal thin film between the supply step and the thin film forming step, and the thin film forming step may be performed by supplying a reaction gas and heating or plasma treating the compound represented by Chemical Formula 1.

There are no particular restrictions on the precursor supply method, manufacturing conditions, manufacturing equipment, etc., and well-known general conditions and methods can be used.

The method of forming a metal thin film using the precursor for forming a metal thin film according to embodiments of inventive concepts may be performed by atomic layer deposition (ALD), chemical vapor deposition (CVD), or a combination thereof.

In particular, in the atomic layer deposition (ALD), by repeating a process of adsorbing molecules of raw material compounds to the surface of a gas installed in a vacuum vessel, a deposition process by reaction between molecules adsorbed on the surface of the gas and a reactive gas, and a removing process of excess molecules by purging, atomic layers are stacked one layer at a time, and uniform film control at the level of one atomic layer becomes possible, making it possible to form a film with high homogeneity and high step coverage. However, compared to chemical vapor deposition (CVD), atomic layer deposition (ALD) has the problem that film formation at high temperatures is difficult and carbon tends to remain in the film.

When a thin film was manufactured at a temperature exceeding about 300° C. by atomic layer deposition (ALD), a lot of carbon may remain in the film.

However, the metal thin film manufactured using raw material gas obtained by vaporizing the raw material including the aforementioned precursor for forming the metal thin film according to an embodiment has excellent thermal stability and has low residual carbon and residual chlorine even at a film forming temperature of about 500° C. or higher and high-quality metal thin films can be manufactured.

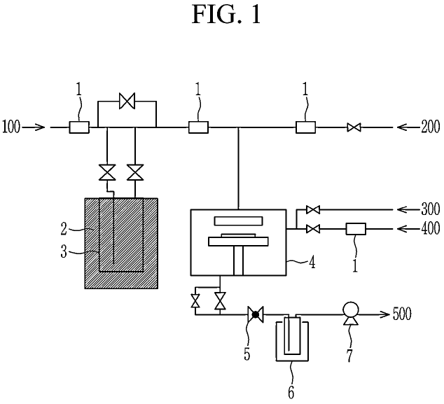

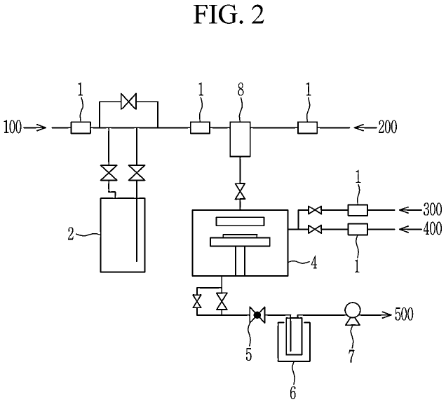

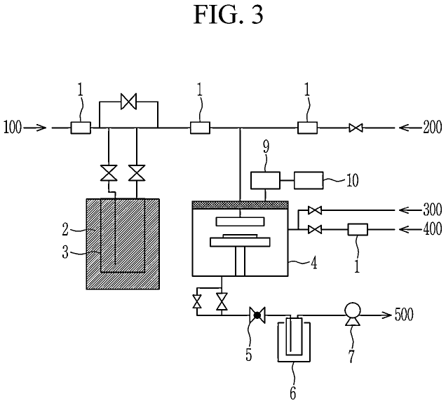

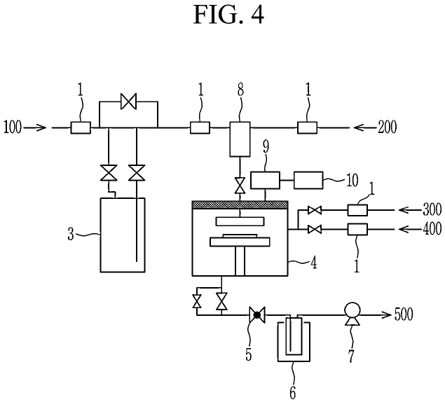

As equipment for manufactured a metal thin film using the precursor for forming a metal thin film according to embodiments of inventive concepts, a known ALD equipment can be used. Examples of specific equipment include an equipment capable of supplying precursors by bubbling, as shown in FIGS. 1 and 3, and equipment with a vaporization chamber 8, as shown in FIGS. 2 and 4. Additionally, as shown in FIGS. 3 and 4, there is equipment capable of plasma processing the reaction gas. In addition, in addition to single-wafer type equipment equipped with the deposition chamber 4 as shown in FIGS. 1 to 4, equipment that can simultaneously process multiple layers using batches is also available. Additional CVD equipment may be also available.

Hereinafter, each step of the manufacturing method of this metal thin film will be described.

In addition, the precursor for forming a metal thin film used in the method for manufacturing a metal thin film according to embodiments of inventive concepts is the same as described in the “precursor for forming a metal film,” and therefore detailed description is omitted.

In embodiments of inventive concepts, the precursor supply step is to supply the raw material gas obtained by vaporizing the precursor for forming a metal thin film into a deposition chamber where the substrate is placed.

The method for supplying the raw material gas obtained by vaporizing the precursor for forming the metal thin film into the deposition chamber where the substrate is placed may include a gas supply method, a liquid supply method, a single source method, and a cocktail source method.

The gas supply method may be, for example, as shown in FIGS. 1 and 3, a method of heating or vaporizing a precursor for forming a metal thin film to create a raw material gas in the raw material container 3 where the precursor for forming a metal thin film is stored, and then supplying the raw material gas, along with carrier gases 100 and 200 such as argon, nitrogen, or helium as needed, into the deposition chamber 4 where the substrate is placed. A heater 3 (e.g., lamp, heating circuit) may surround the raw material container 3 and heat the raw material gas in the raw material container 3. Piping and mass flow controllers 1 may control the supply of the carrier gas 200 into the raw material container 3, the supply of the raw material gas from the raw material container 3 into the deposition chamber 4 and the supply of the carrier gas 200, purge gas 300, and reaction gas 400 into the deposition chamber 4.

The liquid supply method may be, for example, as shown in FIGS. 2 and 4, a method of supplying the precursor for forming a metal thin film in a liquid or solution state to the vaporization chamber 8, heating or vaporizing the raw material for forming a metal thin film in a vaporization chamber to create a raw material gas, and then supplying the raw material gas into the deposition chamber 4. An automatic pressure controller 5, cooling trap 6, and vacuum pump 500 may be connected to the deposition chamber 4 through piping and valves and transport exhaust 500 from the deposition chamber 500 and/or control a pressure in the deposition chamber 4. As shown in FIG. 3, an RF matching system 9 and radio frequency power supply 10 may be connected to the deposition chamber 4 and may be configured to generate a plasma in the deposition chamber 4.

The single source method may be a method of supplying precursors for forming a metal thin film including multi-component precursors, and includes a method of vaporizing and supplying each precursor independently.

The cocktail sauce method may be, for example, a method of vaporizing and supplying mixed raw materials in which multi-component precursors are previously mixed to a desired composition. The precursor for forming a metal thin film containing a multi-component precursor may include the nucleophilic reagent described above.

The process of vaporizing the precursor for forming a metal thin film according to embodiments of inventive concepts into raw material gas may be performed in the raw material container 3 or in the vaporization chamber 8, as described above. In some embodiments of forming a high-quality metal thin film, the precursor for forming a metal thin film may be vaporized at about 0° C. to about 200° C.

In addition, when the precursor for forming a metal thin film is vaporized in the raw material container 3 or in the vaporization chamber 8 to create a raw material gas, the pressure inside the raw material container and the pressure inside the vaporization chamber are suitably within the range of about 1 Pa to about 10,000 Pa from the viewpoint of easy vaporization of the precursor for forming a metal thin film.

The material of the substrate placed in the deposition chamber 4 may include, for example, silicon; ceramics such as silicon nitride, titanium nitride, tantalum nitride, titanium oxide, molybdenum oxide, zirconium oxide, hafnium oxide, and lanthanum oxide; glass; metal films such as cobalt metal and molybdenum metal.

The shape of the substrate includes plates, spheres, fibers, and scales. The surface of the substrate may be flat or may have a three-dimensional structure such as a trench structure.

The metal thin film forming step is to form a zirconium-containing thin film or hafnium-containing thin film on the surface of the substrate by heating or plasma processing the compound shown in Chemical Formula 1 (hereinafter, “heating or plasmaizing” may be expressed as heating, etc.).

In the metal thin film forming step, as shown in FIGS. 1 to 4, in the metal thin film forming process performed within the deposition chamber 4 where the substrate is placed, by heating the compound in the raw material gas supplied to the deposition chamber, the compound is decomposed, and zirconium metal or hafnium metal or a compound containing zirconium and hafnium is adsorbed on the surface of the substrate, thereby forming a zirconium-containing thin film or a hafnium-containing thin film. FIGS. 1 to 4 are examples of heating the compound of the raw material gas supplied into the deposition chamber by supplying the reaction gas 400. In this example, a zirconium-containing thin film or a hafnium-containing thin film is formed by a reaction of the compound and the reaction gas.

The heating temperature of the compound in the metal thin film forming step may range from room temperature (about 25° C.) to 700° C., and from the viewpoint of forming a high-quality zirconium-containing thin film or hafnium-containing thin film, the range of about 200° C. to about 600° C. may be suitable.

In the metal thin film forming step, the conditions for plasma treatment by applying a voltage to the compound may be about 10 W to about 1,500 W, specifically about 50 W to about 600 W, because damage to the substrate is large if the power is too strong.

The plasma may be any one of RF plasma, DC plasma, or remote plasma, and the plasma treatment may be performed using plasma gas containing at least one of helium (He), argon (Ar), and ammonia (NH₃).

From the viewpoint that when adding the precursor thin film forming step described later between the supply step and the thin film forming step, it is easy to obtain high-quality zirconium-containing thin films or hafnium-containing thin films with low residual carbon, it is suitable to supply a reaction gas and heat or plasma treat the compound and it is more suitable to supply a reaction gas and heat the compound. Examples of the reaction gas may include water vapor (H₂O); oxidizing gases such as oxygen (O₂), ozone (O₃), hydrogen peroxide (H₂O₂), nitrogen monoxide (NO), nitrogen dioxide (NO₂), formic acid, acetic acid, and acetic anhydride; reducing gases such as hydrogen (H₂); organic amine compounds such as monoalkylamine, dialkylamine, trialkylamine, and alkylenediamine; or nitriding compounds such as ammonia (NH₃) and hydrazine (N₂H₄), and the like.

These reaction gases may be used individually, or two or more types may be used in combination. Among these reaction gases, a reaction gas containing at least one of hydrogen, ammonia, oxygen, and ozone may be used from the viewpoint of forming a high-quality zirconium-containing thin film or hafnium-containing thin film with low residual carbon or residual chlorine. The compound described in Chemical Formula 1 has the property of reacting particularly well with nitriding gases, and thus it is more suitable to use nitriding gases such as ammonia as a reaction gas.

The method for manufacturing a metal thin film according to embodiments of inventive concepts may further include a precursor thin film forming step of forming a precursor thin film on the surface of a substrate using a precursor for forming a metal thin film between the supply step and the thin film forming step, wherein the precursor thin film is sufficient as long as it can form a zirconium-containing thin film or a hafnium-containing thin film in the thin film forming step.

This precursor thin film may be formed by adsorbing the compound shown in Chemical Formula 1 in the raw material gas supplied into the deposition chamber in which the substrate is placed on the surface of the substrate. At this time, the substrate may be heated or the inside of the deposition chamber may be heated.

The conditions for forming the precursor thin film are not particularly limited, and for example, a reaction temperature (substrate temperature when the compound is adsorbed to the substrate surface), a reaction pressure (pressure inside the deposition chamber when the compound is adsorbed to the substrate surface), an adsorption speed, etc. may be appropriately selected according to the type of precursor for forming a metal thin film. From the viewpoint of uniformly forming the precursor thin film, the reaction temperature may range from about 0° C. to about 700° C., specifically, from about 200° C. to about 600° C. Additionally, the reaction pressure may be about 0.01 to about 300 Pa.

After forming the precursor thin film in the precursor thin film forming step, or after forming the zirconium-containing thin film or hafnium-containing thin film in the thin film forming step, in order to remove non-adsorbed substances or to remove by-product gas and remaining reaction gas after injection of the reaction gas, the method for manufacturing a metal thin film according to embodiments of inventive concepts may include an exhaust process for exhausting unreacted reaction gas and by-product gas from the inside of the deposition chamber. At this time, it is ideal for the non-adsorbed raw material gas, reaction gas, and by-product gas to be completely exhausted from the deposition chamber, but it is not necessarily necessary to completely exhaust them. Examples of the exhaust method may include a method of purging the inside of the deposition chamber with an inert gas such as helium, nitrogen, or argon, a method of depressurizing and exhausting the inside of the chamber, and a method of combining these. From the viewpoint of sufficient exhaustion of unreacted gas and by-product gas, the pressure when depressurizing the chamber may be about 0.01 Pa to about 300 Pa, and more specifically, about 0.01 to about 100 Pa.

In the method of manufacturing a metal thin film according to embodiments of inventive concepts, in order to further improve electrical properties of the zirconium-containing thin film or the hafnium-containing thin film, a heat treatment (annealing) process may be added after forming the thin film. The heat treatment process may be performed in an inert atmosphere, oxidizing atmosphere, or reducing atmosphere, and if a step difference needs to be filled, a reflow process may be added. From the viewpoint of manufacturing a high-quality zirconium-containing thin film or hafnium-containing thin film with low residual carbon or residual chlorine, the temperature of the heat treatment process may be about 250° C. to about 500° C.

The method for producing a metal thin film according to embodiments of inventive concepts may be a method of performing the thin film forming process only once, or may be a method of performing the thin film forming process two or more times. In embodiments of inventive concepts, the raw material gas supply step, precursor thin film forming step, exhaust process, thin film forming step, and exhaust process may be performed in this order, and the formation of a zirconium-containing thin film or hafnium-containing thin film through a series of operations may be considered as one cycle. The cycle may be repeated several times until a zirconium-containing thin film or hafnium-containing thin film of the required thickness is obtained, to form a zirconium-containing thin film or hafnium-containing thin film with the desired thickness. The thickness of the formed zirconium-containing thin film or hafnium-containing thin film may be controlled by the number of cycles. An adsorption rate of the zirconium-containing thin film or hafnium-containing thin film obtained per cycle may be within the range of about 0.001 nm/min to about 100 nm/min, and about 0.005 nm/min to about 50 nm/min, from the viewpoint of producing a uniform zirconium-containing thin film or hafnium-containing thin film.

### Metal Thin Film Formed Using Precursor for Forming Metal Thin Film

Thin films formed using the raw materials for forming metal thin films according to embodiments of inventive concepts may be obtained as thin films such as zirconium metal, hafnium metal zirconium oxide, hafnium oxide, zirconium nitride, and hafnium nitride. However, with the aforementioned method for manufacturing a metal thin film, thin films of zirconium nitride and hafnium nitride may be manufactured with high efficiency. The metal thin film according to embodiments of inventive concepts may be made into a desired type of metal thin film by appropriately selecting different precursors, reaction gases, and manufacturing conditions in the aforementioned method for manufacturing a metal thin film. Since the metal thin film according to embodiments of inventive concepts has excellent electrical and optical properties, it may be widely used, for example, in the production of an electrode material for memory devices such as DRAM devices, a wiring material used in semiconductor devices such as logic, diamagnetic film used as the memory layer of a hard disk, and catalyst materials for solid polymer fuel cells.

Although example embodiments have been described above, inventive concepts are not limited to the aforementioned example embodiments, and various additions, omissions, substitutions, and changes may be made. Additionally, it is possible to provide other embodiments by combining elements from different embodiments.

Hereinafter, the configuration and effects according to embodiments of inventive concepts will be described in more detail through specific examples and comparative examples, but these examples are only intended to provide a clearer understanding according to embodiments of inventive concepts and are not intended to limit the scope according to embodiments of inventive concepts.

### (Synthesis of Compounds for Forming Metal Thin Film)

### Examples 1 to 11 and Comparative Examples 1 to 3

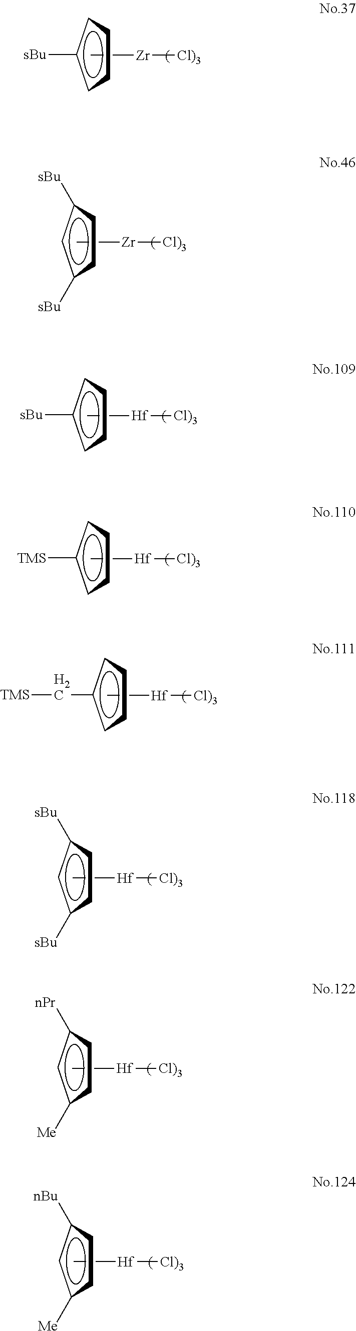

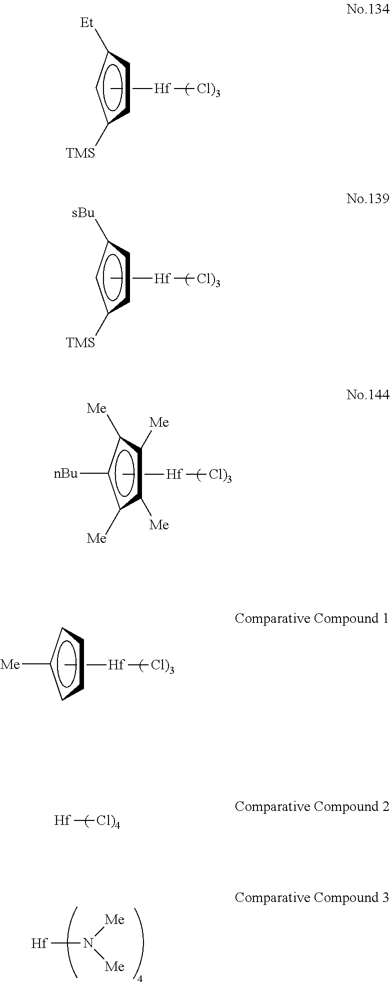

### Example 1: Synthesis of Compound No. 37

In an argon atmosphere, 20 g of zirconium tetrachloride and 100 g of dehydrated toluene were added to the reaction flask. After cooling this to 50° C., 16.7 g of 1-sec-butyl-3-trimethylsilylcyclopentadiene was slowly dropped therein. After refluxing for 6 hours, the solvent was removed, and the obtained product was purified by distillation at 150° C. to 170° C. under reduced pressure of 30 Pa to obtain Compound No. 37 (yield: 15 g, yield: 55%).

### (Analysis Value)

### (1) Elemental Analysis (Metal Analysis: ICP-AES)

Zr: 28.59% (theoretical value: 28.62%), C: 33.92% (theoretical value: 33.91%), H: 4.13% (theoretical value: 4.11%), CI: 33.36% (theoretical value: 33.36%)

(2)¹H-NMR (Solvent: Hexadeuterobenzene) (Chemical shift: Multiplicity: H number)

(0.636:t:3H), (1.049:d:3H), (1.215:m:2H), (2.871:m:1H), (6.137:m:4H)

### (3) Normal Pressure TG-DTA

Temperature at 50 wt % reduction: 235° C. (Argon flow rate: 100 mL/min, temperature increase: 10° C./min, sample quantity: 10.210 mg)

### Example 2: Synthesis of Compound No. 46

In an argon atmosphere, 20 g of zirconium tetrachloride and 100 g of dehydrated toluene were added to the reaction flask. After cooling this to 5° C., 21.5 g of 1,3-di-sec-butyl-4-trimethylsilylcyclopentadiene was slowly dropped therein. After refluxing for 6 hours, the solvent was removed, and the obtained product was purified by distillation at 150° C. to 170° C. under reduced pressure of 30 Pa to obtain Compound No. 46 (yield: 18 g, yield: 56%).

### (Analysis Value)

### (1) Elemental Analysis (Metal Analysis: ICP-AES)

Zr: 24.38% (theoretical value: 24.33%), C: 41.63% (theoretical value: 41.65%), H: 5.63% (theoretical value: 5.65%), Cl: 28.36% (theoretical value: 28.37%)

### (2)¹H-NMR (Solvent: Hexadeuterobenzene)(Chemical Shift: Multiplicity: H Number)

(0.617:m:6H), (1.043:m: 6H), (1.198:m: 4H), (2.728:m: 2H), (6.063:m: 3H)

### (3) Normal Pressure TG-DTA

Temperature at 50 wt % reduction: 243° C. (Argon flow rate: 100 mL/min, temperature increase: 10° C./min, sample quantity: 10.051 mg)

### Example 3: Synthesis of Compound No. 109

In an argon atmosphere, 20 g of hafnium tetrachloride and 100 g of dehydrated toluene were added to the reaction flask. After cooling this to 5° C., 12.1 g of 1-sec-butyl-3-trimethylsilylcyclopentadiene was slowly dropped therein. After refluxing for 6 hours, the solvent was removed, and the obtained product was purified by distillation at 150° C. to 170° C. under reduced pressure of 30 Pa to obtain Compound No. 109 (yield: 17 g, yield: 67%).

### (Analysis Value)

### (1) Elemental Analysis (Metal Analysis: ICP-AES)

Hf: 44.01% (theoretical value: 43.96%), C: 26.62% (theoretical value: 26.62%), H: 3.22% (theoretical value: 3.23%), CL: 26.15% (theoretical value: 26.19%)

### (2)¹H-NMR (Solvent: Hexadeuterobenzene) (Chemical Shift: Multiplicity: H Number)

(0.575:t:3H), (0.972:d:3H), (1.205:m: 2H), (2.633:m: 1H), (5.863:m: 4H)

### (3) Normal Pressure TG-DTA

Temperature at 50 wt % reduction: 212° C. (Argon flow rate:100 mL/min, temperature increase: 10° C./min, sample quantity: 10.033 mg)

### Example 4: Synthesis of Compound No. 110

In an argon atmosphere, 20 g of hafnium tetrachloride and 100 g of dehydrated toluene were added to the reaction flask. After cooling this to 5° C., 13.1 g of 1,3-bistrimethylsilylcyclopentadiene was slowly dropped therein. After refluxing for 6 hours, the solvent was removed, and the obtained product was purified by distillation at 150° C. to 170° C. under reduced pressure of 30 Pa to obtain Compound No. 110 (yield: 18 g, yield: 68%).

### (Analysis Value)

### (1) Elemental Analysis (Metal Analysis: ICP-AES)

Hf: 42.26% (theoretical value: 42.28%), Si: 6.67% (theoretical value: 6.65%), C: 22.75% (theoretical value: 22.76%), H: 3.09% (theoretical value: 3.10%), Cl: 25.22% (theoretical value: 25.19%)

### (2)¹H-NMR (Solvent: Hexadeuterobenzene)(Chemical Shift: Multiplicity: H Number)

(0.124:s:9H), (1.038:m: 6H), (1.170:m: 4H), (2.638:m: 2H), (6.011:m: 4H)

### (3) Normal Pressure TG-DTA

Temperature at 50 wt % reduction: 199° C. (Argon flow rate: 100 mL/min, temperature increase: 10° C./min, sample quantity: 9.634 mg)

### Example 5: Synthesis of Compound No. 111

In an argon atmosphere, 20 g of hafnium tetrachloride and 100 g of dehydrated toluene were added to the reaction flask. After cooling this to 5° C., 14.0 g of 1-methyltrimethylsilyl-3-trimethylsilylcyclopentadiene was slowly dropped therein. After refluxing for 6 hours, the solvent was removed, and the obtained product was purified by distillation at 150° C. to 170° C. under reduced pressure of 30 Pa to obtain Compound No. 111 (yield: 10 g, yield: 37%).

### (Analysis Value)

### (1) Elemental Analysis (Metal Analysis: ICP-AES)

Hf: 40.90% (theoretical value: 40.92%), Si: 6.45% (theoretical value: 6.44%), C: 24.76% (theoretical value: 24.79%), H: 3.48% (theoretical value: 3.47%), Cl: 24.40% (theoretical value: 24.38%)

### (2)¹H-NMR (Solvent: Hexadeuterobenzene)(Chemical Shift: Multiplicity: H Number)

(−0.281:s:9H), (1.870:s: 2H), (1.170:m: 4H), (2.638:m: 2H), (5.797:m: 2H)

### (3) Normal Pressure TG-DTA

Temperature at 50 wt % reduction: 216° C. (Argon flow rate:100 mL/min, temperature increase: 10° C./min, sample quantity: 10.135 mg)

### Example 6: Synthesis of Compound No. 118

In an argon atmosphere, 20 g of hafnium tetrachloride and 100 g of dehydrated toluene were added to the reaction flask. After cooling this to 5° C., 15.7 g of 1,3-di-sec-butyl-4-trimethylsilylcyclopentadiene was slowly dropped therein. After refluxing for 6 hours, the solvent was removed, and the obtained product was purified by distillation at 150° C. to 170° C. under reduced pressure of 30 Pa to obtain Compound No. 118 (yield: 21 g, yield: 73%).

### (Analysis Value)

### (1) Elemental Analysis (Metal Analysis: ICP-AES)

Hf: 38.58% (theoretical value: 38.62%), C: 33.81% (theoretical value: 33.79%), H: 4.59% (theoretical value: 4.58%), Cl: 23.02% (theoretical value: 23.01%)

### (2)¹H-NMR (Solvent: Hexadeuterobenzene)(Chemical Shift: Multiplicity: H Number)

(0.634:m: 6H), (1.038:m: 6H), (1.170:m: 4H), (2.638:m: 2H), (5.938:m: 3H)

### (3) Normal Pressure TG-DTA

Temperature at 50 wt % reduction: 240° C. (Argon flow rate:100 mL/min, temperature increase: 10° C./min, sample quantity: 9.507 mg)

### Example 7: Synthesis of Compound No. 122

In an argon atmosphere, 20 g of hafnium tetrachloride and 100 g of dehydrated toluene were added to the reaction flask. After cooling this to 5° C., 12.1 g of 1-methyl-3-normal propyl-4-trimethylsilylcyclopentadiene was slowly dropped therein. After refluxing for 6 hours, the solvent was removed, and the obtained product was purified by distillation at 150° C. to 170° C. under reduced pressure of 30 Pa to obtain Compound No. 122 (yield: 16 g, yield: 63%).

### (Analysis Value)

### (1) Elemental Analysis (Metal Analysis: ICP-AES)

Hf: 44.00% (theoretical value: 43.96%), C: 26.60% (theoretical value: 26.62%), H: 3.24% (theoretical value: 3.23%), Cl: 26.16% (theoretical value: 26.19%)

### (2)¹H-NMR (Solvent: Hexadeuterobenzene)(Chemical Shift: Multiplicity: H Number)

(0.669:t:3H), (1.257:m: 2H), (1.936:s: 3H), (2.345:t: 2H), (5.648:m: 3H)

### (3) Normal Pressure TG-DTA

Temperature at 50 wt % reduction: 207° C. (Argon flow rate: 100 mL/min, temperature increase: 10° C./min, sample quantity: 10.404 mg)

### Example 8: Synthesis of Compound No. 124

In an argon atmosphere, 20 g of hafnium tetrachloride and 100 g of dehydrated toluene were added to the reaction flask. After cooling this to 5° C., 13.0 g of 1-methyl-3-normal butyl-4-trimethylsilylcyclopentadiene was slowly dropped therein. After refluxing for 6 hours, the solvent was removed, and the obtained product was purified by distillation at 150° C. to 170° C. under reduced pressure of 30 Pa to obtain Compound No. 124 (yield: 17 g, yield: 65%).

### (Analysis Value)

### (1)Elemental Analysis (Metal Analysis: ICP-AES)

Hf: 42.51% (theoretical value: 42.49%), C: 28.61% (theoretical value: 28.59%), H: 3.55% (theoretical value: 3.60%), Cl: 25.33% (theoretical value: 25.32%)

### (2)¹H-NMR (Solvent: Hexadeuterobenzene)(Chemical Shift: Multiplicity: H Number)

(0.763:t: 3H), (1.076:m: 2H), (1.214:m: 2H), (1.942:s: 3H), (2.401:t: 3H), (5.612:m: 3H)

### (3) Normal Pressure TG-DTA

Temperature at 50 wt % reduction: 219° C. (Argon flow rate: 100 mL/min, temperature increase: 10° C./min, sample quantity: 9.957 mg)

### Example 9: Synthesis of Compound No. 134

In an argon atmosphere, 20 g of hafnium tetrachloride and 100 g of dehydrated toluene were added to the reaction flask. After cooling this to 5° C., 14.9 g of 1-ethyl-2,4-bistrimethylsilylcyclopentadiene was slowly dropped therein. After refluxing for 6 hours, the solvent was removed, and the obtained product was purified by distillation at 150° C. to 170° C. under reduced pressure of 30 Pa to obtain Compound No. 134 (yield: 19 g, yield: 68%).

### (Analysis Value)

### (1)Elemental Analysis (Metal Analysis: ICP-AES)

Hf: 39.66% (theoretical value: 39.65%), Si: 6.26% (theoretical value: 6.24%), C: 26.66% (theoretical value: 26.68%), H: 3.82% (theoretical value: 3.81%), Cl: 23.60% (theoretical value: 23.62%)

### (2)¹H-NMR (Solvent: Hexadeuterobenzene)(Chemical Shift: Multiplicity: H Number)

(0.163:s: 9H), (0.921:t: 3H), (2.437:d:2H), (6.240:m: 3H)

### (3) Normal Pressure TG-DTA

Temperature at 50 wt % reduction: 220° C. (Argon flow rate: 100 mL/min, temperature increase: 10° C./min, sample quantity: 9.824 mg)

### Example 10: Synthesis of Compound No. 139

In an argon atmosphere, 20 g of hafnium tetrachloride and 100 g of dehydrated toluene were added to the reaction flask. After cooling this to 5° C., 16.65 g of 1-sec-butyl-2,4-bistrimethylsilylcyclopentadiene was slowly dropped therein. After refluxing for 6 hours, the solvent was removed, and the obtained product was purified by distillation at 150° C. to 170° C. under reduced pressure of 30 Pa to obtain Compound No. 139 (yield: 20 g, yield: 67%).

### (Analysis Value)

### (1)Elemental Analysis (Metal Analysis: ICP-AES)

Hf: 37.35% (theoretical value: 37.32%), Si: 5.86% (theoretical value: 5.87%), C: 30.13% (theoretical value: 30.14%), H: 4.44% (theoretical value: 4.43%), Cl: 22.22% (theoretical value: 22.24%)

### (2)¹H-NMR (Solvent: Hexadeuterobenzene)(Chemical Shift: Multiplicity: H Number)

(0.196:s: 9H), (0.629:t: 3H), (1.030:d: 3H), (1.205:m: 2H), (2.788:m: 1H), (2.638:m: 2H), (6.264:m: 1H)

### (3) Normal Pressure TG-DTA

Temperature at 50 wt % reduction: 210° C. (Argon flow rate: 100 mL/min, temperature increase: 10° C./min, sample quantity: 9.486 mg)

### Example 11: Synthesis of Compound No. 144

In an argon atmosphere, 20 g of hafnium tetrachloride and 100 g of dehydrated toluene were added to the reaction flask. After cooling this to 5° C., 15.7 g of 1-trimethylsilyl-1 n-butyl-2,3,4,5-tetramethylcyclopentadiene was slowly dropped therein. After refluxing for 6 hours, the solvent was removed, and the obtained product was purified by distillation at 150° C. to 170° C. under reduced pressure of 30 Pa to obtain Compound No. 144 (yield: 19 g, yield: 66%).

### (Analysis Value)

### (1)Elemental Analysis (Metal Analysis: ICP-AES)

Hf: 38.54% (theoretical value: 38.62%), C: 33.83% (theoretical value: 33.79%), H: 4.60% (theoretical value: 4.58%), Cl: 23.03% (theoretical value: 23.01%)

### (2)¹H-NMR (Solvent: Hexadeuterobenzene)(Chemical Shift: Multiplicity: H Number)

(0.770:t: 3H), (1.098:m: 4H), (1.905:d: 12H), (2.483:t: 2H)

### (3)Normal Pressure TG-DTA

Temperature at 50 wt % reduction: 241° C. (Argon flow rate: 100 mL/min, temperature increase: 10° C./min, sample quantity: 9.887 mg)

### Evaluation Examples: Evaluation of Physical Properties of Compounds

Evaluation was conducted with the compounds according to Examples 1 to 11 and Comparative Compounds 1 to 3.

‘Me’ in Comparative Compound 1 represents a methyl group.

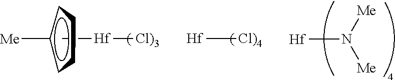

### (Comparative Compound 1) (Comparative Compound 2) (Comparative Compound 3)

### (1) Evaluation of Room Temperature and Melting Point

Properties of the compounds were visually examined under a normal pressure (760 Torr) at room temperature (25° C.). Among them, solid materials at 25° C. was measured with respect to a melting point by using an M.P. measuring equipment, and the results are shown in Table 1.

### (2) Evaluation of Thermal Stability

A differential scanning calorimeter (DSC) was used to measure a temperature when a pyrolysis started, and the results are shown in Table 1.

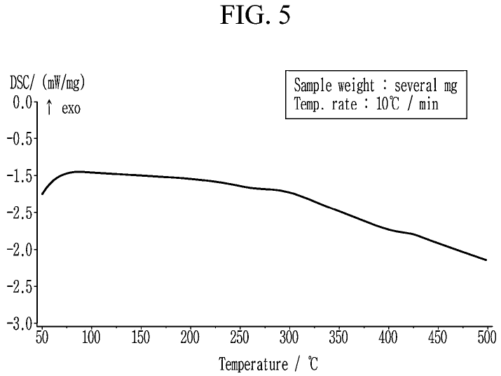

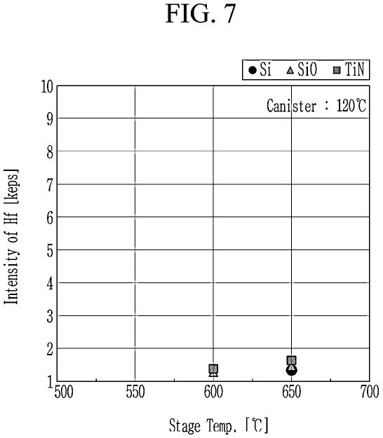

In addition, Examples 6 to 10 in a liquid state under a normal pressure at room temperature were measured with respect to a temperature (DSC₀) at which a thermal decomposition peak started to appear, a temperature (TG 50) at which the mass of each sample was halved by using a TGA measuring equipment to measure a weight change of a material according to a temperature change, and a residue of the sample (TGA Residue) after completing the thermal decomposition, and the results are shown in Table 2, and in particular, the DSC analysis result e.g., the thermal decomposition result according to a growth rate of a deposition film and a temperature change of Example 8 are respectively shown in FIGS. 5 to 7.

### (3) Viscosity

A ball-falling viscometer (product name: AMVn, Anton Paar GmbH) was used to measure viscosity at room temperature (25° C.), and the results are shown in Table 2.

TABLE 1

| | | Phase | | |
|---|---|---|---|---|
| | | under normal | | Thermal |
| | | pressure (760 | | decomposition |
| | | Torr) at room | Melting | start |
| | | temperature | point | temperature |
| | Compound | (25° C.) | (° C.) | (° C.) |
| Example 1 | No. 37 | solid | 150 | >500 |
| Example 2 | No. 46 | solid | 140 | >500 |
| Example 3 | No. 109 | solid | 59 | >500 |
| Example 4 | No. 110 | solid | 50 | >500 |
| Example 5 | No. 111 | solid | 107 | >500 |
| Example 6 | No. 118 | liquid | — | >500 |
| Example 7 | No. 122 | liquid | — | >500 |
| Example 8 | No. 124 | liquid | — | >500 |
| Example 9 | No. 134 | liquid | — | >500 |
| Example 10 | No. 139 | liquid | — | >500 |
| Example 11 | No. 144 | solid | 64 | >500 |
| Comparative | Comparative | solid | 89 | 138 |
| Example 1 | Compound 1 | | | |
| Comparative | Comparative | solid | 434 | >500 |
| Example 2 | Compound 2 | | | |
| Comparative | Comparative | solid | 32 | 279 |
| Example 3 | Compound 3 | | | |

TABLE 2

| | Example 6 | Example 7 | Example 8 | Example 9 |
|---|---|---|---|---|
| | liquid | liquid | liquid | liquid |
| Viscosity (cPs) | 57.9 | 145.4 | 98.6 | 22.9 |
| TC 50 (° C.) | 240 | 207 | 219 | 209 |
| TGA Residue (%) | 99.2 | 98.2 | 97.7 | 99.5 |
| DSC₀ (° C.) | none | none | none | none |
| ALD window | −650° C. | −650° C. | −650° C. | −650° C. |

Referring to Tables 1 and 2, compounds with a low melting point are easy to supply and thus judged to be suitable as raw materials for forming a thin film.

Comparative Compound 2 exhibited a melting point of 434° C., but Examples 1 to 5 and 11 according to embodiments of inventive concepts exhibited a melting point of less than 150° C. and turned out to be easily supplied and suitable as raw materials.

On the other hand, Comparative Examples 1 to 3 exhibited a high melting point at room temperature under a normal pressure and turned out to be disadvantageous when supplied.

In particular, since Examples 6 to 10 according to embodiments of inventive concepts were liquid at room temperature under a normal pressure, wherein a liquid deposition material is much more advantageous to supply.

In addition, since a compound with a high thermal decomposition-starting temperature is difficult to be thermally decomposed, the compound is judged to be not suitable as a raw material for forming a thin film.

The thermal decomposition-starting temperature of Comparative Compound 1 was 138° C., and that of Comparative Compound 2 was 279° C., but the compounds according to the present examples exhibited a thermal decomposition-starting temperature of greater than 500° C., which confirms to be thermally stable and thus suitable for forming a thin film.

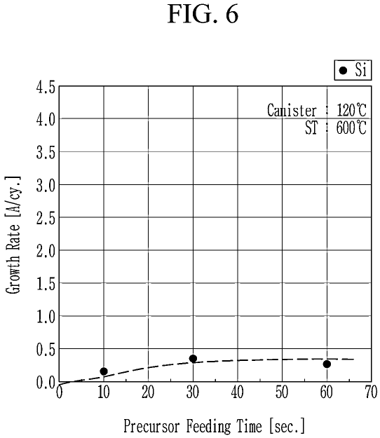

Referring to FIGS. 5 to 7, the compounds according to the present examples turned out to be stable even at 500° C. without thermal decomposition (FIG. 5) and particularly, after 30 seconds even at a deposition temperature of 600° C., formed a uniform deposited film by maintaining its saturated state without decomposition (FIG. 6), and were not decomposed at 600° C. or more and specifically, even to 650° C. (FIG. 8).

Accordingly, compounds for forming a metal thin film with excellent thermal stability were prepared.

### (Manufacture of Thin Films by ALD)

The compounds of Examples 1 to 11 and Comparative Examples 1 to 3 were used as raw materials for chemical vapor growth to form a hafnium nitride thin film or a zirconium nitride thin film on a silicon wafer by ALD under the following conditions using an equipment of FIG. 1.

The obtained thin film was measured with respect to a thickness through X-ray reflectometry and also, with respect to a carbon content and a chlorine content through X-ray photoelectron spectroscopy, and the results are shown in Table 3.

Examples 12 to 22 and Comparative Examples 4 to 6: Manufacture of zirconium nitride thin film and hafnium nitride thin film by ALD

### (Conditions)

Reaction temperature (wafer temperature): 300° C., reaction gas: ammonia gas

### (Process)

The processes consisting of (1) to (4) were regarded as 1 cycle and were repeated 50 cycles.

(1) The raw materials were vaporized and supplied for chemical vapor growth in a container heated at 90° C. under an internal pressure of 100 Pa and then, deposited under the internal pressure of 100 Pa for 10 seconds (a raw material supply and precursor thin film forming process).

(2) Unreacted raw materials were removed for 10 seconds by purging with argon (an exhaust process).

(3) Reaction gas was supplied to react the raw materials under the chamber internal pressure of 100 Pa for 20 seconds (a thin film forming process).

(4) Unreacted raw materials were removed again for 10 seconds by purging with argon (an exhaust process).

TABLE 3

| | Raw | | | C | CI |
|---|---|---|---|---|---|
| | materials | | | content | content |
| | for | | | in thin | in thin |
| | chemical | Thickness | | film | film |
| | vapor growth | (nm) | Thin film | (atm %) | (atm %) |
| Example 12 | No. 37 | 3.9 | zirconium | Not | Not |
| | | | nitride | detected | detected |
| Example 13 | No. 46 | 3.8 | zirconium | Not | Not |
| | | | nitride | detected | detected |
| Example 14 | No. 109 | 4.3 | hafnium | Not | Not |
| | | | nitride | detected | detected |
| Example 15 | No. 110 | 4.6 | hafnium | Not | Not |
| | | | nitride | detected | detected |
| Example 16 | No. 111 | 4.1 | hafnium | Not | Not |
| | | | nitride | detected | detected |
| Example 17 | No. 118 | 5.3 | hafnium | Not | Not |
| | | | nitride | detected | detected |
| Example 18 | No. 122 | 4.8 | hafnium | Not | Not |
| | | | nitride | detected | detected |
| Example 19 | No. 124 | 4.9 | hafnium | Not | Not |
| | | | nitride | detected | detected |
| Example 20 | No. 134 | 5.4 | hafnium | Not | Not |
| | | | nitride | detected | detected |
| Example 21 | No. 139 | 5.1 | hafnium | Not | Not |
| | | | nitride | detected | detected |
| Example 22 | No. 144 | 4.2 | hafnium | Not | Not |
| | | | nitride | detected | detected |
| Comparative | Comparative | 2.9 | hafnium | 3 | Not |
| Example 4 | Compound 1 | | nitride | | detected |
| Comparative | Comparative | 2.0 | hafnium | Not | 0.6 |
| Example 5 | Compound 2 | | nitride | detected | |
| Comparative | Comparative | 2.7 | hafnium | 5 | Not |
| Example 6 | Compound 3 | | nitride | | detected |

### (Detection Limit: 0.1 Atm %)

Referring to Table 3, the carbon content of the hafnium nitride or zirconium nitride thin film obtained by ALD was 3 at % or more in Comparative Examples 4 and 6 but in Examples 12 to 22 (not detected), less than the detection limit to 0.1 atm %.

In addition, the chlorine content in the hafnium nitride or zirconium nitride thin film obtained by ALD was 0.6 atm % in Comparative Example 4 but in Examples 12 to 22, less than the detection limit to 0.1 atm % (not detected).

In other words, the compounds according to embodiments of inventive concepts were used to form a hafnium nitride or zirconium nitride thin film with high quality.

In addition, the thin films of Comparative Examples 4 to 6 had a thickness of 2.9 nm or less, but the thin films of Examples 12 to 22 had a thickness of 3.8 nm or more, and accordingly, the compounds according to embodiments of inventive concepts may be used to improve producibility of the hafnium nitride thin film or zirconium nitride thin film.

Among them, the thin films of Examples 15 and 17 to 21 had a thickness of 4.6 nm or more to achieve much higher producibility.

In particular, the thin films of Examples 17, 20, and 21 had a thickness of 5.1 nm or more, forming a nitride thin film with particularly high producibility.

From the above, the compounds according to embodiments of inventive concepts were liquid or solid but had a low melting point and thus high thermal stability, which may be used as raw materials for chemical vapor growth to form a high-quality thin film with high producibility.

In particular, Compound No. 118, Compound No. 122, Compound No. 124, Compound No. 134, and Compound No. 139 had a liquid phase and high thermal stability and thus, turned out to further increase producibility when formed into a thin film.

Among them, Compound No. 118, Compound No. 134, and Compound No. 139 having much higher thermal stability turned out to be particularly excellent as a raw material for chemical vapor growth.

While embodiments of inventive concepts have been particularly shown and described with reference to presented embodiments thereof, it is to be understood that embodiments of inventive concepts are not limited to the presented embodiments, but, on the contrary, is intended to cover various modifications and equivalent arrangements included within the spirit and scope of the appended claims.

### DESCRIPTION OF SYMBOLS

1: MFC (Mass Flow Controller)
2: heater
3: raw material container
4: deposition chamber
5: automatic pressure controller
6: cooling trap
7: vacuum pump
8: vaporization chamber
9: RF matching system
10: radio frequency (RF) power
100: carrier gas-1
200: carrier gas-2
300: purge gas
400: reaction gas
500: exhaust

What is claimed is:

1. A precursor for forming a metal thin film, the precursor comprising a metal compound represented by Chemical Formula 1: 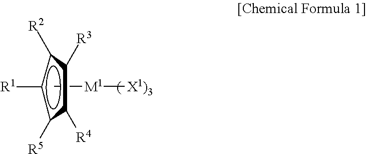
wherein, in Chemical Formula 1,
M¹ is a Group 4 metal,
X¹ is a halogen atom, and
R¹, R², R³, R⁴, and R⁵ are each independently a hydrogen atom, a substituted or unsubstituted C1 to C5 alkyl group, or a ligand represented by (L-1), or a combination of the ligand represented by (L-1) and a substituted or unsubstituted C1 to C5 alkyl group, provided that at least one of R¹, R², R³, R⁴, or R⁵ includes a substituted or unsubstituted C1 to C5 alkyl group or the ligand represented by (L-1), 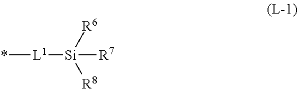
wherein, in (L-1), R⁶, R⁷, and R⁸ are each independently a substituted or unsubstituted C1 to C5 alkyl group,
L¹ is a single bond or a substituted or unsubstituted C1 to C5 alkylene group, and
* is a linking point.

2. The precursor of claim 1, wherein
at least two of R¹, R², R³, R⁴, and R⁵ are substituted or unsubstituted C1 to C5 alkyl groups or the ligand represented by (L-1).

3. The precursor of claim 1, wherein
at least one of R¹, R², R³, R⁴, and R⁵ is a substituted or unsubstituted C3 to C5 branched alkyl group or the ligand represented by (L-1).

4. The precursor of claim 1, wherein
one of R¹, R², R³, R⁴, and R⁵ is a substituted or unsubstituted C1 to C5 alkyl groups or the ligand described in (L-1), or
two of R¹, R², R³, R⁴, and R⁵ independently are a substituted or unsubstituted C1 to C5 alkyl groups or the ligand described in (L-1), or
all of R¹, R², R³, R⁴, and R⁵ independently are a substituted or unsubstituted C1 to C5 alkyl groups or the ligand described in (L-1).

5. The precursor of claim 1, wherein
one of R¹, R², R³, R⁴, and R⁵ is a substituted or unsubstituted iso-propyl group, a substituted or unsubstituted iso-butyl group, a substituted or unsubstituted sec-butyl group, a substituted or unsubstituted tert-butyl group, a substituted or unsubstituted iso-pentyl group, a substituted or unsubstituted neo-pentyl group, or a trimethylsilyl group.

6. The precursor of claim 1, wherein
two of R¹, R², R³, R⁴, and R⁵ include a combination of a trimethylsilyl group and one of a substituted or unsubstituted ethyl group, a substituted or unsubstituted n-propyl group, a substituted or unsubstituted iso-propyl group, a substituted or unsubstituted n-butyl group, a substituted or unsubstituted iso-butyl group, a substituted or unsubstituted sec-butyl group, a substituted or unsubstituted tert-butyl group, a substituted or unsubstituted n-pentyl group, a substituted or unsubstituted iso-pentyl group, or a substituted or unsubstituted neo-pentyl group.

7. The precursor of claim 1, wherein
one of R¹, R², R³, R⁴, and R⁵ is a substituted or unsubstituted ethyl group, a substituted or unsubstituted n-propyl group, a substituted or unsubstituted iso-propyl group, a substituted or unsubstituted n-butyl group, a substituted or unsubstituted iso-butyl group, a substituted or unsubstituted sec-butyl group, a substituted or unsubstituted tert-butyl group, or a trimethylsilyl group, and
a remaining four of R¹, R², R³, R⁴, and R⁵ are a substituted or unsubstituted methyl group.

8. The precursor of claim 1, wherein
L¹ of the ligand represented by (L-1) is a single bond or a substituted or unsubstituted methylene group, and
R⁶, R⁷, and R⁸ are independently a substituted or unsubstituted methyl group.

9. The precursor of claim 1, wherein
the Group 4 metal of M¹ is zirconium or hafnium.

10. The precursor of claim 1, wherein
each X¹ is independently F or C1.

11. The precursor of claim 1, wherein the metal compound represented by Chemical Formula 1 is at least one of:
Hf(sec-Bu)Cp(F)₃, Hf(TMS)Cp(F)₃, Hf(TMSCH₂)Cp(F)₃, Hf(Me₂Cp)(F)₃, Hf(Et₂Cp)(F)₃, Hf(n-Pr)₂Cp(F)₃, Hf(iso-Pr)Cp(F)₃, Hf(n-Bu)₂Cp(F)₃, Hf(iso-Bu)₂Cp(F)₃, Hf(sec-Bu)₂Cp(F)₃, Hf(tert-Bu)₂Cp(F)₃, Hf(TMS)₂Cp(F)₃, Hf(Me)(Et)Cp(F)₃, Hf(n-Pr)(Me)Cp(F)₃, Hf(iso-Pr)(Me)Cp(F)₃, Hf(n-Bu)(Me)Cp(F)₃, Hf(iso-Bu)(Me)Cp(F)₃, Hf(sec-Bu)(Me)Cp(F)₃, Hf(tert-Bu)(Me)Cp(F)₃, Hf(n-Pr)(Et)Cp(F)₃, Hf(n-Bu)(Et)Cp(F)₃, Hf(sec-Bu)(Et)Cp(F)₃, Hf(n-Bu)(n-Pr)Cp(F)₃, Hf(sec-Bu)(n-Pr)Cp(F)₃, Hf(Me)(TMS)Cp(F)₃, Hf(Et)(TMS)Cp(F)₃, Hf(n-Pr)(TMS)Cp(F)₃, Hf(iso-Pr)(TMS)Cp(F)₃, Hf(n-Bu)(TMS)Cp(F)₃, Hf(iso-Bu)(TMS)Cp(F)₃, Hf(sec-Bu)(TMS)Cp(F)₃, Hf(tert-Bu)(TMS)Cp(F)₃, Hf(Me₅)Cp(F)₃, Hf(Me₄)(Et)Cp(F)₃, Hf(Me₄)(n-Pr)Cp(F)₃, Hf(Me₄)(n-Bu)Cp(F)₃;
Hf(sec-Bu)Cp(Cl)₃, Hf(TMS)Cp(Cl)₃, Hf(TMSCH₂)Cp(Cl)₃, Hf(Me₂Cp)(Cl)₃, Hf(Et₂Cp)(Cl)₃, Hf(n-Pr)₂Cp(Cl)₃, Hf(iso-Pr)Cp(Cl)₃, Hf(n-Bu)₂Cp(Cl)₃, Hf(iso-Bu)₂Cp(Cl)₃, Hf(sec-Bu)₂Cp(Cl)₃, Hf(tert-Bu)₂Cp(Cl)₃, Hf(TMS)₂Cp(Cl)₃, Hf(Me)(Et)Cp(Cl)₃, Hf(n-Pr)(Me)Cp(Cl)₃, Hf(iso-Pr)(Me)Cp(Cl)₃, Hf(n-Bu)(Me)Cp(Cl)₃, Hf(iso-Bu)(Me)Cp(Cl)₃, Hf(sec-Bu)(Me)Cp(Cl)₃, Hf(tert-Bu)(Me)Cp(Cl)₃, Hf(n-Pr)(Et)Cp(Cl)₃, Hf(n-Bu)(Et)Cp(Cl)₃, Hf(sec-Bu)(Et)Cp(Cl)₃, Hf(n-Bu)(n-Pr)Cp(Cl)₃, Hf(sec-Bu)(n-Pr)Cp(Cl)₃, Hf(Me)(TMS)Cp(Cl)₃, Hf(Et)(TMS)Cp(Cl)₃, Hf(n-Pr)(TMS)Cp(Cl)₃, Hf(iso-Pr)(TMS)Cp(Cl)₃, Hf(n-Bu)(TMS)Cp(Cl)₃, Hf(iso-Bu)(TMS)Cp(Cl)₃, Hf(sec-Bu)(TMS)Cp(Cl)₃, Hf(tert-Bu)(TMS)Cp(Cl)₃, Hf(Me₅)Cp(Cl)₃, Hf(Me₄)(Et)Cp(Cl)₃, Hf(Me₄)(n-Pr)Cp(Cl)₃, Hf(Me₄)(n-Bu)Cp(Cl)₃;
Zr(sec-Bu)Cp(F)₃, Zr(TMS)Cp(F)₃, Zr(TMSCH₂)Cp(F)₃, Zr(Me₂Cp)(F)₃, Zr(Et₂Cp)(F)₃, Zr(n-Pr)₂Cp(F)₃, Zr(iso-Pr)Cp(F)₃, Zr(n-Bu)₂Cp(F)₃, Zr(iso-Bu)₂Cp(F)₃, Zr(sec-Bu)₂Cp(F)₃, Zr(tert-Bu)₂Cp(F)₃, Zr(TMS)₂Cp(F)₃, Zr(Me)(Et)Cp(F)₃, Zr(n-Pr)(Me)Cp(F)₃, Zr(iso-Pr)(Me)Cp(F)₃, Zr(n-Bu)(Me)Cp(F)₃, Zr(iso-Bu)(Me)Cp(F)₃, Zr(sec-Bu)(Me)Cp(F)₃, Zr(tert-Bu)(Me)Cp(F)₃, Zr(n-Pr)(Et)Cp(F)₃, Zr(n-Bu)(Et)Cp(F)₃, Zr(sec-Bu)(Et)Cp(F)₃, Zr(n-Bu)(n-Pr)Cp(F)₃, Zr(sec-Bu)(n-Pr)Cp(F)₃, Zr(Me)(TMS)Cp(F)₃, Zr(Et)(TMS)Cp(F)₃, Zr(n-Pr)(TMS)Cp(F)₃, Zr(iso-Pr)(TMS)Cp(F)₃, Zr(n-Bu)(TMS)Cp(F)₃, Zr(iso-Bu)(TMS)Cp(F)₃, Zr(sec-Bu)(TMS)Cp(F)₃, Zr(tert-Bu)(TMS)Cp(F)₃, Zr(Me₅)Cp(F)₃, Zr(Me₄)(Et)Cp(F)₃, Zr(Me₄)(n-Pr)Cp(F)₃, Zr(Me₄)(n-Bu)Cp(F)₃; or
Zr(sec-Bu)Cp(Cl)₃, Zr(TMS)Cp(Cl)₃, Zr(TMSCH₂)Cp(Cl)₃, Zr(Me₂Cp)(Cl)₃, Zr(Et₂Cp)(Cl)₃, Zr(n-Pr)₂Cp(Cl)₃, Zr(iso-Pr)Cp(Cl)₃, Zr(n-Bu)₂Cp(Cl)₃, Zr(iso-Bu)₂Cp(Cl)₃, Zr(sec-Bu)₂Cp(Cl)₃, Zr(tert-Bu)₂Cp(Cl)₃, Zr(TMS)₂Cp(Cl)₃, Zr(Me)(Et)Cp(Cl)₃, Zr(n-Pr)(Me)Cp(Cl)₃, Zr(iso-Pr)(Me)Cp(Cl)₃, Zr(n-Bu)(Me)Cp(Cl)₃, Zr(iso-Bu)(Me)Cp(Cl)₃, Zr(sec-Bu)(Me)Cp(Cl)₃, Zr(tert-Bu)(Me)Cp(Cl)₃, Zr(n-Pr)(Et)Cp(Cl)₃, Zr(n-Bu)(Et)Cp(Cl)₃, Zr(sec-Bu)(Et)Cp(Cl)₃, Zr(n-Bu)(n-Pr)Cp(Cl)₃, Zr(sec-Bu)(n-Pr)Cp(Cl)₃, Zr(Me)(TMS)Cp(Cl)₃, Zr(Et)(TMS)Cp(Cl)₃, Zr(n-Pr)(TMS)Cp(Cl)₃, Zr(iso-Pr)(TMS)Cp(Cl)₃, Zr(n-Bu)(TMS)Cp(Cl)₃, Zr(iso-Bu)(TMS)Cp(Cl)₃, Zr(sec-Bu)(TMS)Cp(Cl)₃, Zr(tert-Bu)(TMS)Cp(Cl)₃, Zr(Me₅)Cp(Cl)₃, Zr(Me₄)(Et)Cp(Cl)₃, Zr(Me₄)(n-Pr)Cp(Cl)₃, Zr(Me₄)(n-Bu)Cp(Cl)₃.

12. The precursor of claim 1, wherein the metal compound represented by Chemical Formula 1 is at least one selected from compounds listed in Group 1:

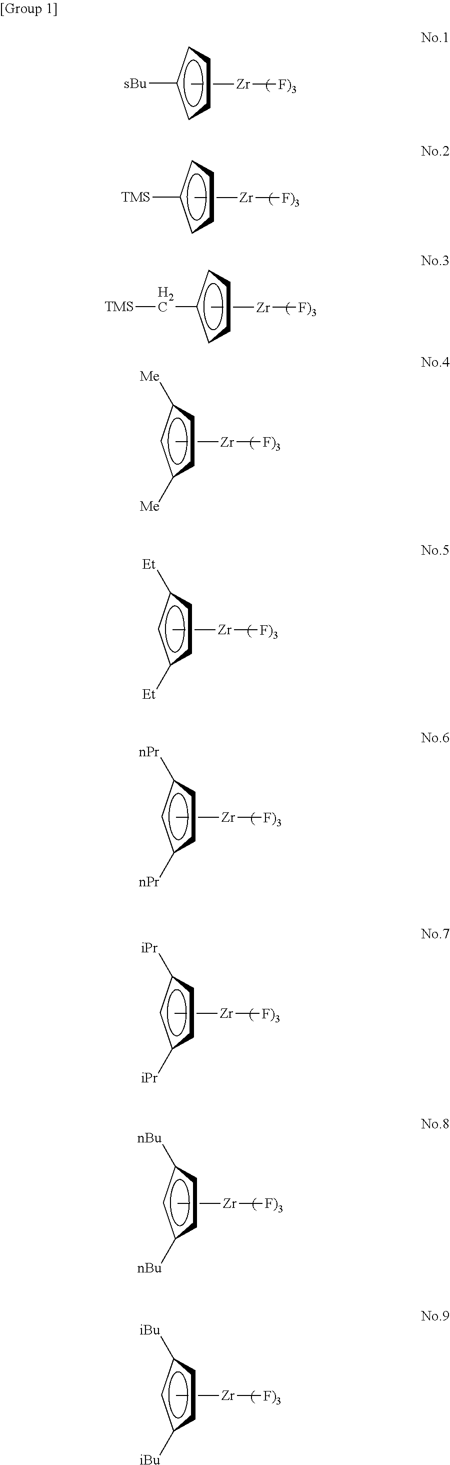

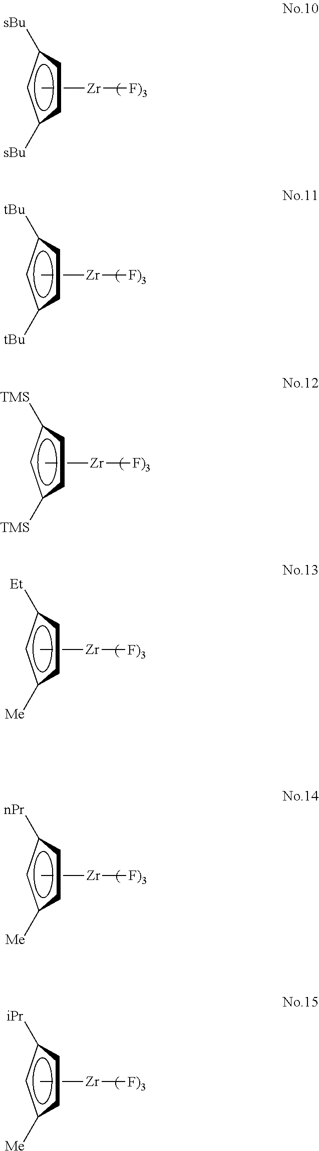

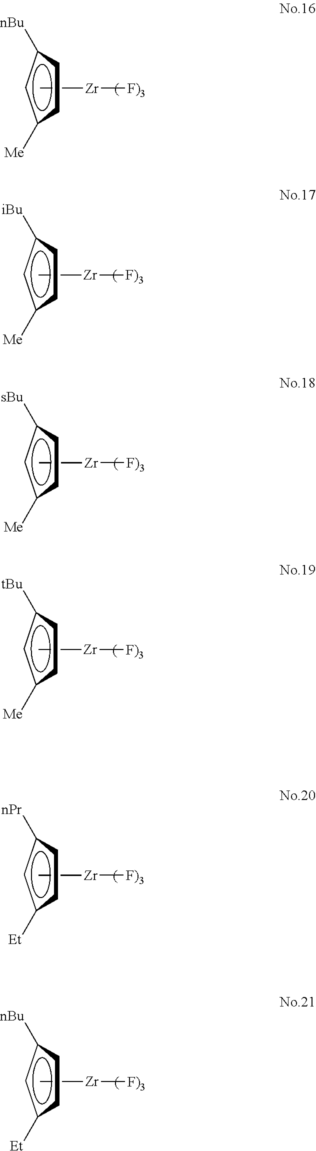

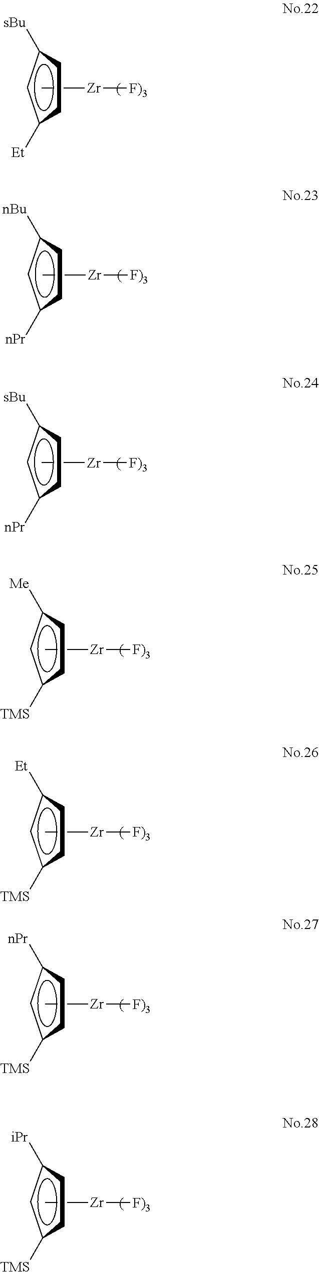

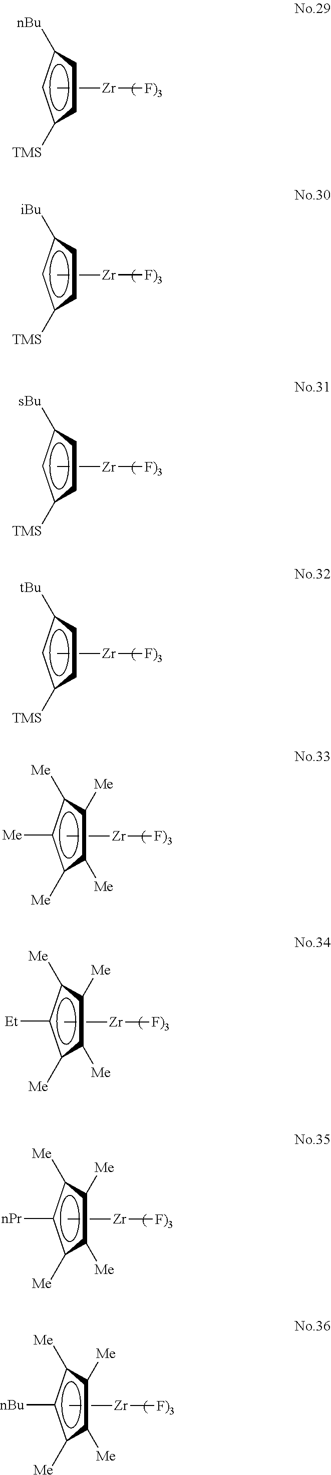

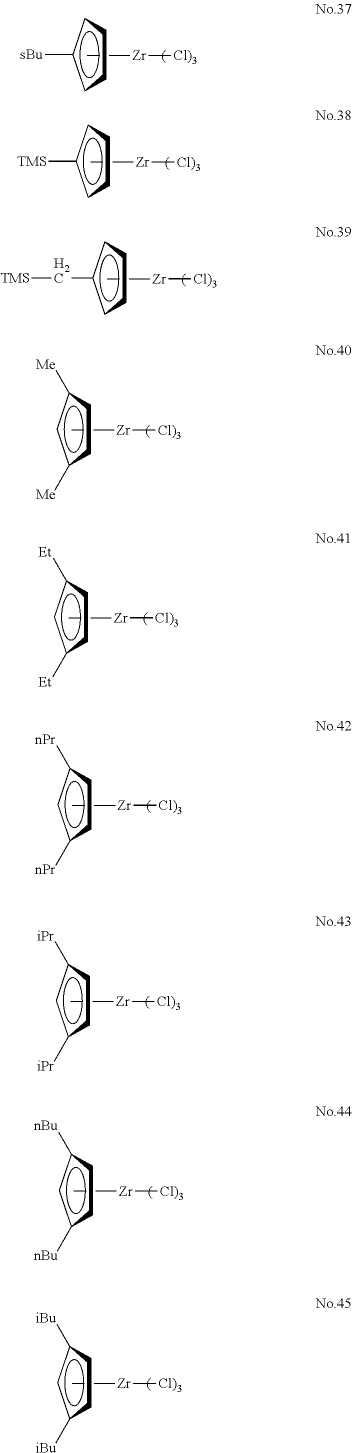

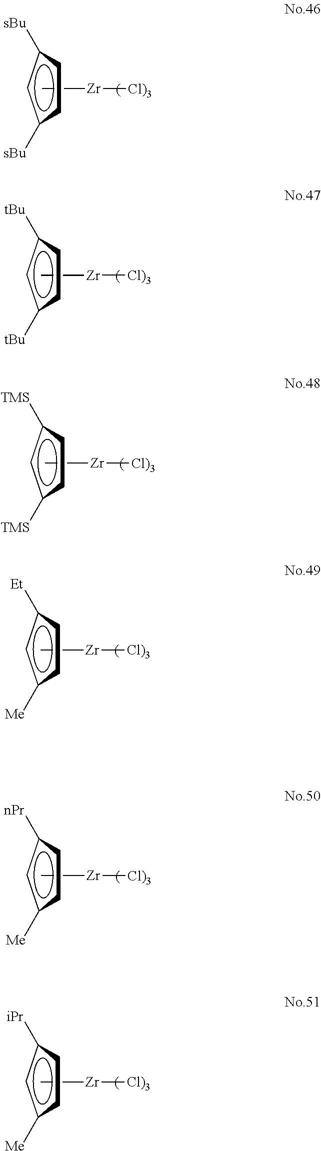

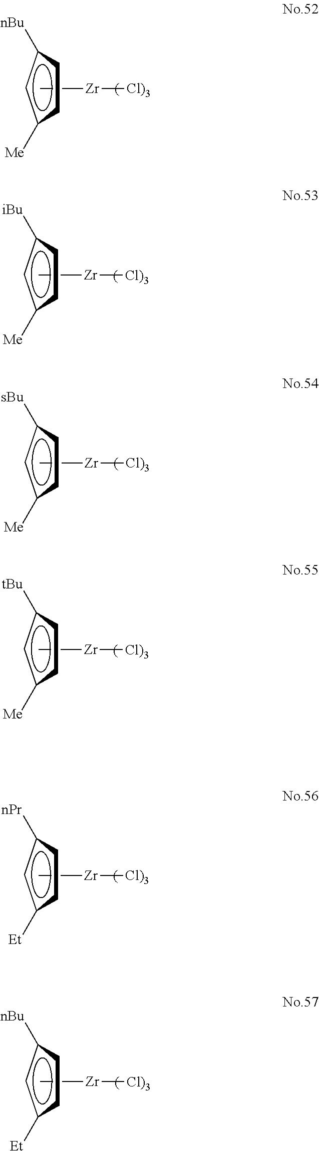

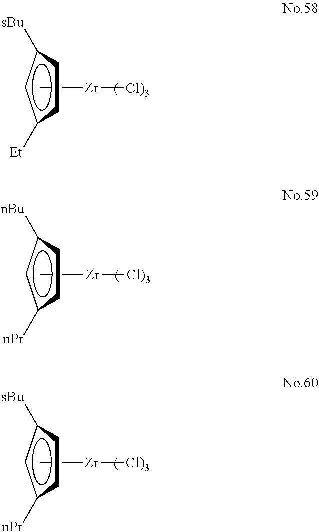

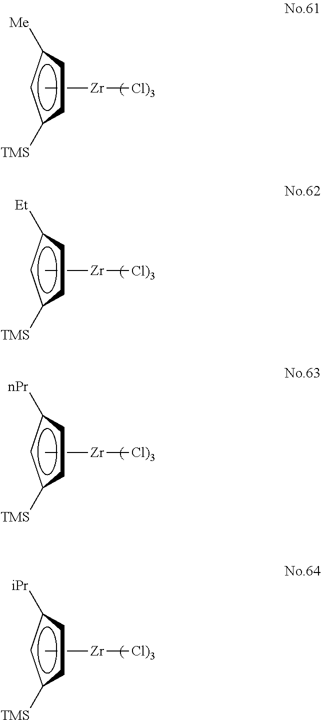

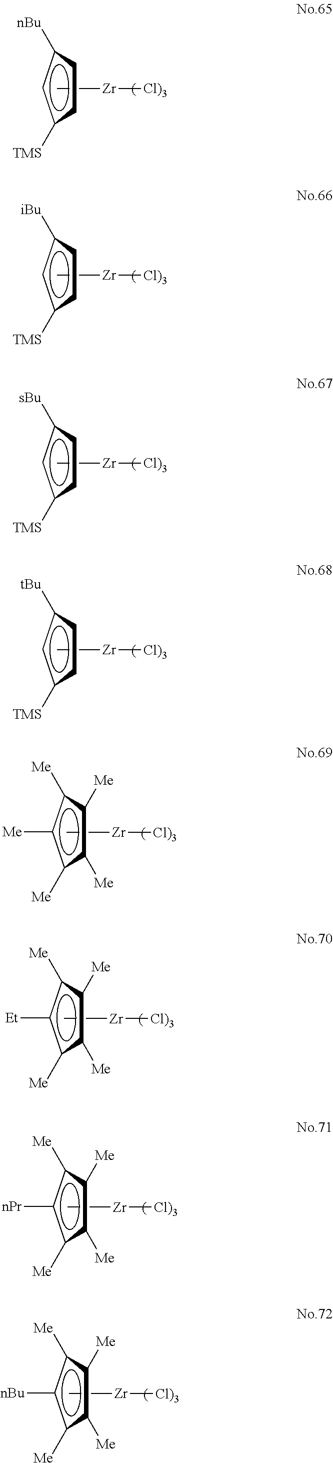

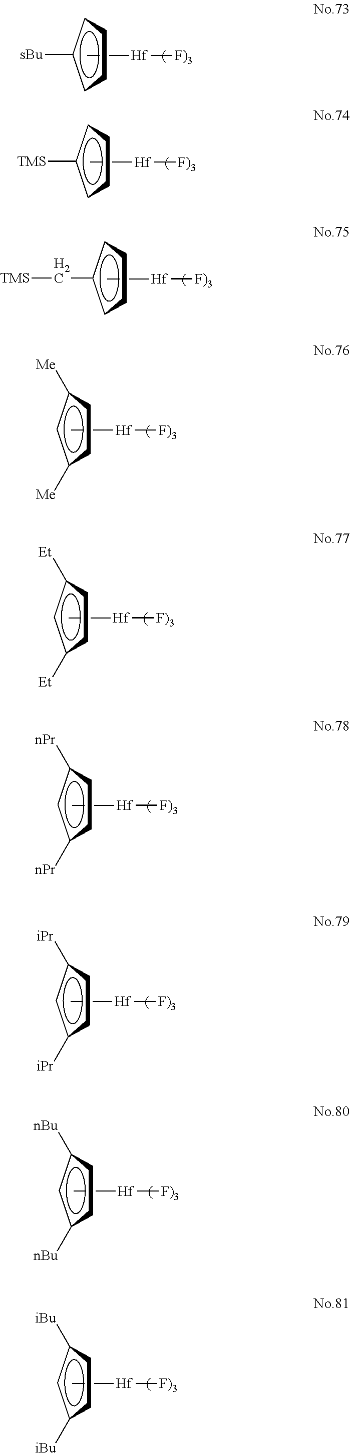

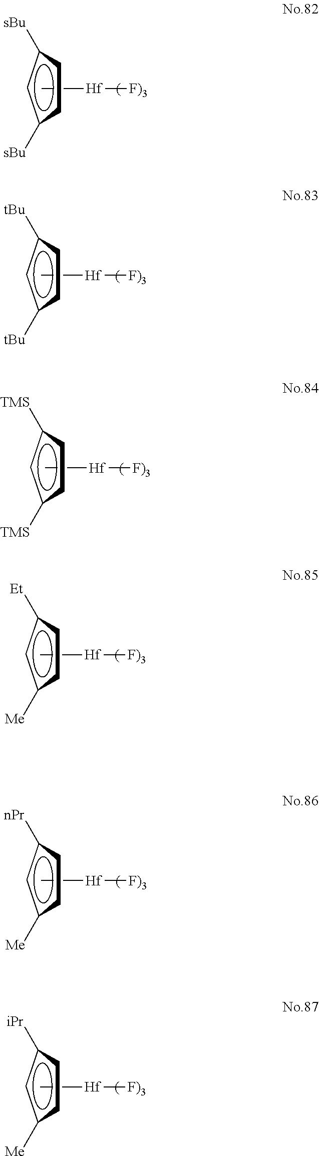

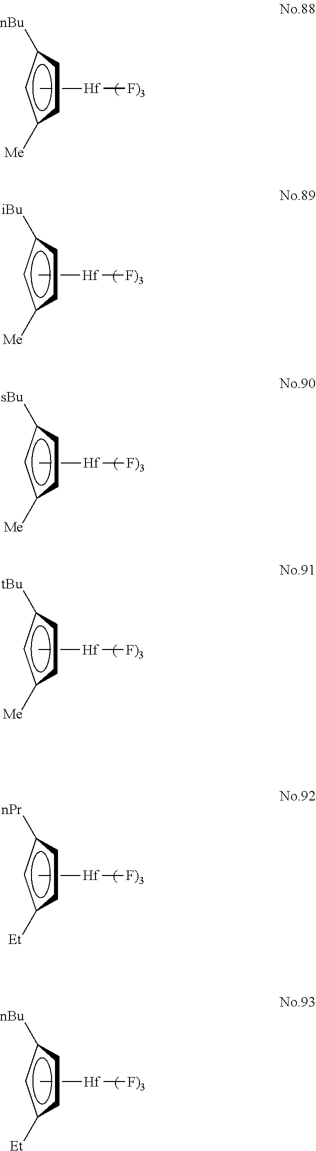

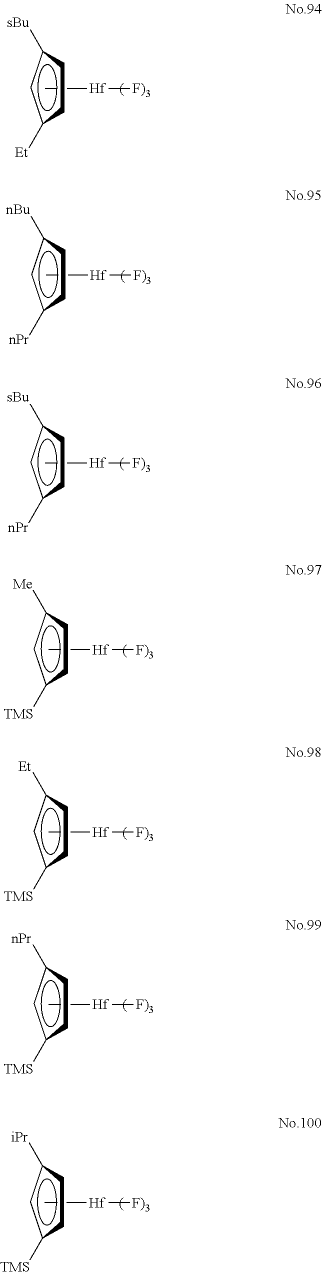

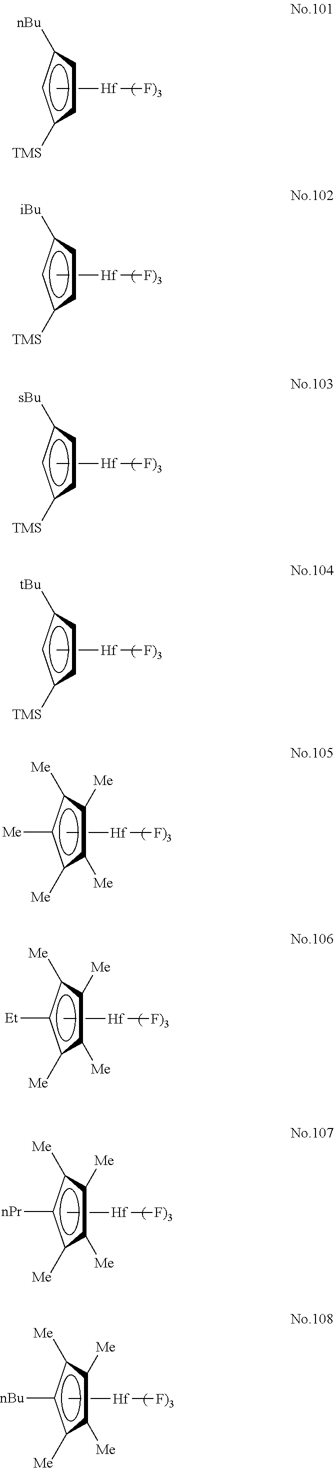

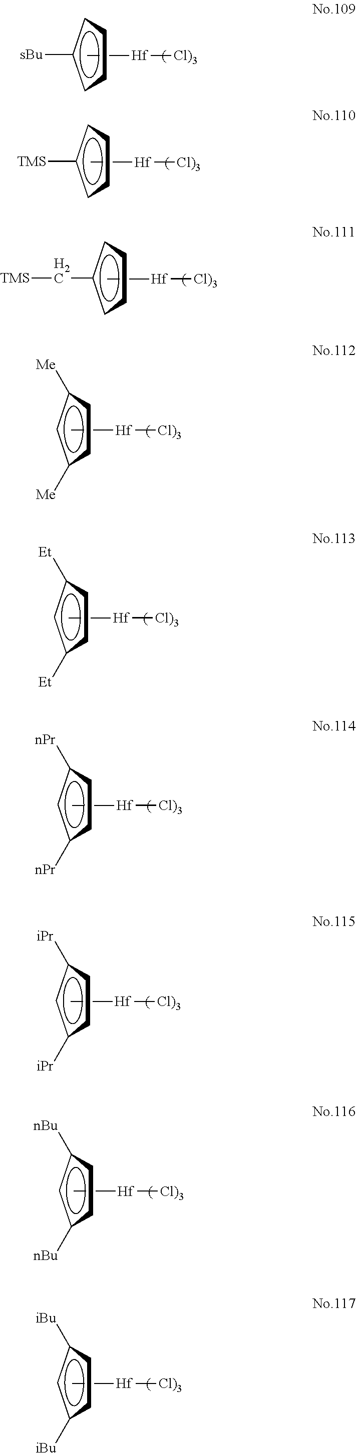

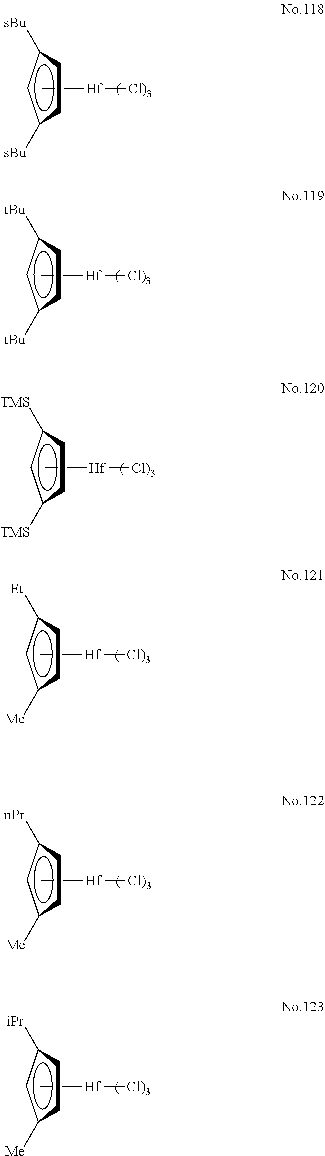

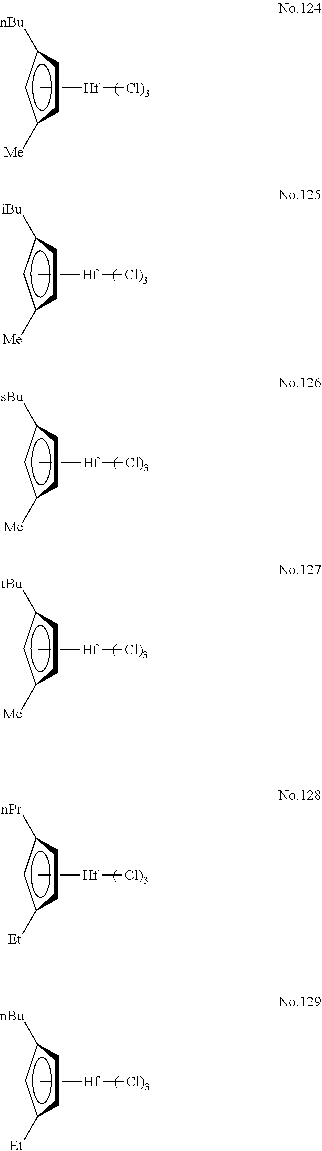

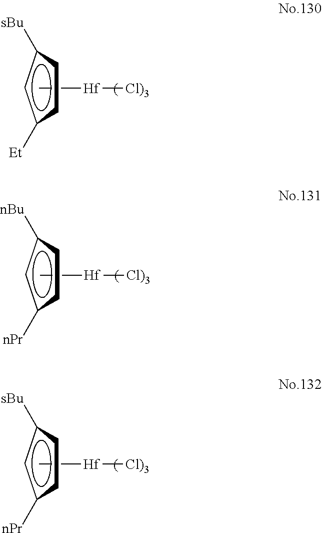

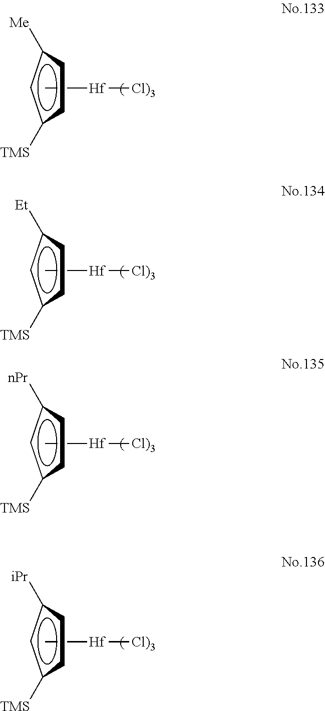

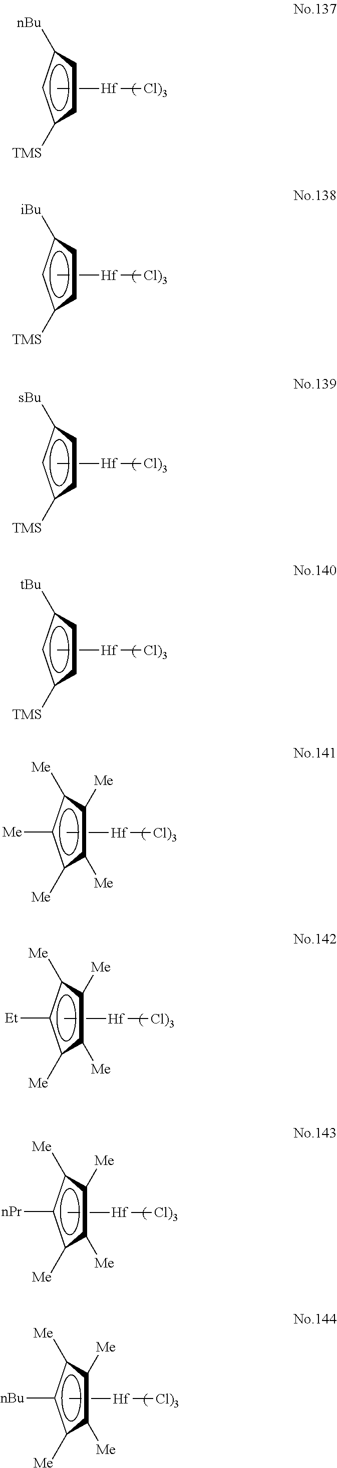

13. The precursor of claim 1, wherein
a thermal decomposition temperature of the metal compound represented by Chemical Formula 1 is 500° C. or higher.

14. A method for manufacturing a metal thin film, comprising
supplying a raw material gas obtained by vaporizing raw materials including the precursor of claim 1 into a deposition chamber; and
forming a metal thin film including a Group 4 metal material on a surface of a substrate by heating or plasma treating the raw material gas while the raw material gas is in the deposition chamber and a substrate is in the deposition chamber.

15. The method of claim 14, further comprising:
forming a precursor thin film on the surface of the substrate using the precursor before the forming the thin film including the Group 4 metal material on the surface of the substrate, wherein
the forming the precursor thin film is performed by supplying the precursor onto the surface of the substrate while the substrate is in the deposition chamber.

16. The method of claim 15, wherein
the forming the precursor thin film includes supplying a reaction gas into the deposition chamber and heating or performing a plasma treatment while the substrate, precursor, and the reaction gas are in the deposition chamber.

17. The method of claim 16, wherein the reaction gas includes at least one of:
water vapor (H₂O);
an oxidizing gas comprising at least one of oxygen (O₂), ozone (O₃), hydrogen peroxide (H₂O₂), nitrogen monoxide (NO), nitrogen dioxide (NO₂), formic acid, acetic acid, or acetic anhydride;
a reducing gas including hydrogen (H₂);
an organic amine compound comprising at least one of monoalkylamine, dialkylamine, trialkylamine, or alkylenediamine; or
a nitriding compound comprising at least one of ammonia (NH₃) or hydrazine (N₂H₄).

18. The method of claim 15, further comprising:
performing an exhaust process, where
the exhaust process includes exhausting gases from inside the deposition chamber after the forming the precursor thin film, or
the exhaust process includes exhausting gases from inside the deposition chamber after the forming the thin film containing the Group 4 metal material of the thin film forming.

19. The method of claim 14, wherein
the plasma treatment is performed at a power of 10 W to 1,500 W using a plasma gas containing at least one of helium (He), argon (Ar), or ammonia (NH₃).

20. A metal thin film manufactured by the method of claim 14.
